(19) United States
(12) Patent Application Publication
(10) Pub. No.: US 2025/0132262 A1
(43) Pub. Date: Apr. 24, 2025

(54) DEVICE WITH SIDE-BY-SIDE INTEGRATED CIRCUIT DEVICES

(71) Applicant: QUALCOMM Incorporated, San Diego, CA (US)

(72) Inventors: Joan Rey Villarba BUOT, Escondido, CA (US); Hong Bok WE, San Diego, CA (US); Zhijie WANG, San Diego, CA (US); Sang-Jae LEE, San Diego, CA (US)

(21) Appl. No.: 18/649,229

(22) Filed: Apr. 29, 2024

Related U.S. Application Data
(63) Continuation-in-part of application No. 18/491,084, filed on Oct. 20, 2023.

(51) Int. Cl. H01L 23/538; H01L 21/48; H01L 23/00; H01L 25/10

(52) U.S. Cl. CPC H01L 23/5386; H01L 21/4857; H01L 23/5383; H01L 25/105; H01L 24/16; H01L 2224/16227

(57) ABSTRACT

A device includes a substrate that includes a first layer stack including metal and dielectric layers. A first metal layer includes first contacts disposed in a first region and to electrically connect to an IC device, via pads disposed in a second region offset along a first direction, and traces electrically connecting the first contacts and the via pads. The substrate includes, in both regions, a solder resist layer disposed on the first metal layer and a first dielectric layer. The solder resist layer defines openings to the first contacts and the via pads. The substrate includes a second layer stack disposed on the second region and including a second metal layer on the solder resist layer opposite the first layer stack. The second metal layer defines second contacts to electrically connect to second IC device(s) and includes conductive vias between the via pads and the second contacts.

### CROSS-REFERENCE TO RELATED APPLICATIONS

The present application claims priority from and is a continuation-in-part of pending U.S. patent application Ser. No. 18/491,084, filed Oct. 20, 2023, and entitled “DEVICE WITH SIDE-BY-SIDE INTEGRATED CIRCUIT DEVICES,” the content of which is incorporated herein by reference in its entirety.

### FIELD

Various features relate to integrated circuit devices.

### BACKGROUND

Electrical connections exist at each level of a system hierarchy. This system hierarchy includes interconnection of active devices at a lowest system level all the way up to system level interconnections at the highest level. For example, interconnect layers can connect different devices together on an integrated circuit. As integrated circuits become more complex, more interconnect layers are used to provide the electrical connections between the devices. More recently, the number of interconnect levels for circuitry has substantially increased due to the large number of devices that are now interconnected in a modern electronic device. The increased number of interconnect levels for supporting the increased number of devices involves more intricate processes.

State-of-the-art applications often demand a small form factor, low cost, a tight power budget, and high electrical performance. Integrated circuit (IC) package design has evolved to try to meet these divergent goals; however, increasing IC device complexity is often associated with increased need for heat dissipation and increased need for device-to-device interconnects, and techniques to address these challenges generally increase cost, reduce performance, and/or increase the size of an IC package.

### SUMMARY

Various features relate to devices including integrated circuits.

One example provides a device that includes a substrate including a first layer stack, a first solder resist layer, and a second layer stack. The first layer stack includes multiple metal layers interspersed with multiple dielectric layers. A first metal layer of the first layer stack includes first contacts disposed in a first region of the first metal layer and configured to electrically connect to a first integrated circuit (IC) device. The first metal layer of the first layer stack also includes via pads disposed in a second region of the first metal layer. The second region is offset along a first direction from the first region. The first metal layer of the first layer stack further includes traces electrically connected to the first contacts and to the via pads. The first solder resist layer is disposed on a surface that includes the first metal layer and a first dielectric layer in the first region and in the second region. The first solder resist layer defines openings to the first contacts and openings to the via pads. The second layer stack is disposed on the second region of the first metal layer and includes a second metal layer disposed on the first solder resist layer opposite the first layer stack. The second metal layer defines second contacts configured to electrically connect to one or more second IC devices. The second layer stack also includes conductive vias extending between the via pads and the second contacts.

Another example provides a method for fabricating a device. The method includes forming a first layer stack that includes multiple metal layers interspersed with multiple dielectric layers. Forming the first layer stack includes forming a first metal layer that includes first contacts disposed in a first region of the first metal layer and configured to electrically connect to a first IC device. The first metal layer also includes via pads disposed in a second region of the first metal layer that is laterally offset from the first region. The first metal layer further includes traces electrically connected to the first contacts and to the via pads. The method also includes forming a first solder resist layer on a surface including the first metal layer and a first dielectric layer in the first region and in the second region. The first solder resist layer defines openings to the first contacts and openings to the via pads. The method includes forming conductive vias electrically connected to the via pads through at least some of the openings in the first solder resist layer. The method further includes forming a second metal layer on the first solder resist layer. The second metal layer defines second contacts electrically connected to the conductive vias. The second contacts are configured to electrically connect to one or more second IC devices.

Another example provides a device that includes one or more first IC devices, one or more second IC devices, and a substrate coupled to the one or more first IC devices and the second IC devices and defining conductive paths therebetween. The substrate includes a first layer stack, a first solder resist layer, and a second layer stack. The first layer stack includes multiple metal layers interspersed with multiple dielectric layers. A first metal layer of the first layer stack includes first contacts disposed in a first region of the first metal layer and electrically connected to the one or more first IC devices. The first metal layer of the first layer stack also includes via pads disposed in a second region of the first metal layer. The second region is offset along a first direction from the first region. The first metal layer of the first layer stack further includes traces electrically connected to the first contacts and to the via pads. The first solder resist layer disposed on a surface including the first metal layer and a first dielectric layer in the first region and in the second region. The first solder resist layer defines openings to the first contacts and openings to the via pads. The second layer stack is disposed on the second region of the first metal layer and includes a second metal layer disposed on the first solder resist layer opposite the first layer stack. The second metal layer defines second contacts electrically connected to the one or more second IC devices. The second layer stack also includes conductive vias extending between the via pads and the second contacts.

### BRIEF DESCRIPTION OF THE DRAWINGS

Various features, nature and advantages may become apparent from the detailed description set forth below when taken in conjunction with the drawings in which like reference characters identify correspondingly throughout.

FIG. 1A illustrates a schematic longitudinal cross-sectional profile view of an exemplary device that includes multiple IC devices interconnected in a side-by-side arrangement.

FIG. 1B illustrates a schematic plan view of a layer of a substrate of the device of FIG. 1A.

FIG. 1C illustrates a schematic transverse cross-section view of the substrate of the device 100 of FIG. 1A.

FIG. 2A illustrates a schematic longitudinal cross sectional profile view of another exemplary device that includes multiple IC devices interconnected in a side-by-side arrangement.

FIG. 2B illustrates a schematic plan view of a layer of a substrate of the device of FIG. 2A.

FIG. 3A illustrates a schematic longitudinal cross sectional profile view of another exemplary device that includes multiple IC devices interconnected in a side-by-side arrangement.

FIG. 3B illustrates a schematic plan view of a layer of a substrate of the device of FIG. 3A.

FIGS. 4A, 4B, 4C, 4D, and 4E, together, illustrate an example of a sequence for fabricating an exemplary device that includes multiple IC devices interconnected in a side-by-side arrangement.

FIG. 5A illustrates a schematic longitudinal cross-sectional profile view of an exemplary device that includes multiple IC devices interconnected in a side-by-side arrangement on a substrate that includes one or more solder resist layers.

FIG. 5B illustrates a schematic plan view of a layer of a substrate of the device of FIG. 5A.

FIG. 5C illustrates a schematic transverse cross-section view of the substrate of the device 500 of FIG. 5A.

FIGS. 6A, 6B, 6C, and 6D, together, illustrate an example of a sequence for fabricating an exemplary device that includes multiple IC devices interconnected in a side-by-side arrangement on a substrate that includes one or more solder resist layers.

FIG. 7 illustrates a flow diagram of an example of a method for fabricating an exemplary device that includes multiple IC devices interconnected in a side-by-side arrangement.

FIG. 8 illustrates a flow diagram of an example of a method for fabricating an exemplary device that includes multiple IC devices interconnected in a side-by-side arrangement on a substrate that includes one or more solder resist layers.

FIG. 9 illustrates various electronic devices that may integrate a die, an electronic circuit, an integrated device, a device, a package, and/or a device package described herein.

### DETAILED DESCRIPTION

In the following description, specific details are given to provide a thorough understanding of the various aspects of the disclosure. However, it will be understood by one of ordinary skill in the art that the aspects may be practiced without these specific details. For example, circuits may be shown in block diagrams in order to avoid obscuring the aspects in unnecessary detail. In other instances, well-known circuits, structures and techniques may not be shown in detail in order not to obscure the aspects of the disclosure.

Particular aspects of the present disclosure are described below with reference to the drawings. In the description, common features are designated by common reference numbers. As used herein, various terminology is used for the purpose of describing particular implementations only and is not intended to be limiting of implementations. For example, the singular forms “a,” “an,” and “the” are intended to include the plural forms as well, unless the context clearly indicates otherwise. Further, some features described herein are singular in some implementations and plural in other implementations. For ease of reference herein, such features are generally introduced as “one or more” features and are subsequently referred to in the singular or optional plural (as indicated by “(s)”) unless aspects related to multiple of the features are being described.

As used herein, the terms “comprise,” “comprises,” and “comprising” may be used interchangeably with “include,” “includes,” or “including.” As used herein, “exemplary” indicates an example, an implementation, and/or an aspect, and should not be construed as limiting or as indicating a preference or a preferred implementation. As used herein, an ordinal term (e.g., “first,” “second,” “third,” etc.) used to modify an element, such as a structure, a component, an operation, etc., does not by itself indicate any priority or order of the element with respect to another element, but rather merely distinguishes the element from another element having a same name (but for use of the ordinal term). As used herein, the term “set” refers to one or more of a particular element, and the term “plurality” refers to multiple (e.g., two or more) of a particular element.

Improvements in manufacturing technology and demand for lower cost and more capable electronic devices has led to increasing complexity of ICs. Often, more complex ICs have more complex interconnection schemes to enable interaction between ICs of a device. The number of interconnect levels for circuitry has substantially increased due to the large number of devices that are now interconnected in a state-of-the-art IC package or device.

These interconnections include back-end-of-line (BEOL) interconnect layers, which may refer to the conductive interconnect layers for electrically coupling to front-end-of-line (FEOL) active devices of an IC. The various BEOL interconnect layers are formed at corresponding BEOL interconnect levels, in which lower BEOL interconnect levels generally use thinner metal layers relative to upper BEOL interconnect levels. The BEOL interconnect layers may electrically couple to middle-of-line (MOL) interconnect layers, which interconnect to the FEOL active devices of an IC.

State-of-the-art IC packages and devices demand a small form factor, low cost, a tight power budget, and high electrical performance. IC package design has evolved to better meet these divergent goals. For example, fan-out (FO) wafer level packaging (WLP) or FO-WLP process technology is a development in packaging technology that is useful for certain IC packages, such as IC packages for mobile applications. This chip first FO-WLP process technology solution provides flexibility to fan-in and fan-out connections from a die to package balls. In addition, this solution also provides a height reduction of a first level interconnect between the die and the package balls of mobile application devices. These mobile applications, however, are susceptible to power and signal routing issues when multiple dies are arranged within the small form factor.

As used herein, the term “layer” includes a film, and is not to be construed as indicating a vertical or horizontal thickness unless otherwise stated. As used herein, the term “chiplet” may refer to an integrated circuit block, a functional circuit block, or other like circuit block specifically designed to work with one or more other chiplets to form a larger, more complex chiplet architecture.

Aspects of the present disclosure are directed to a device that includes two or more IC devices coupled next to each other (e.g., in a side-by-side arrangement) on a substrate. Positioning certain IC devices (e.g., flip-chip devices or surface-mountable packages) side by side on a substrate can limit routing options for traces that provide conductive paths between the devices. For example, each flip-chip device generally includes an array of contacts on a side facing the substrate, and the substrate has a corresponding array of contacts facing the flip-chip device. Solder balls, solder bumps, pillar bumps, or similar interconnects connected to the flip-chip device are aligned with and then connected to the contacts of the substrate. The contacts of the substrate are formed large enough to facilitate correct alignment of the interconnects with the contacts of the flip-chip device during this process. Thus, the contacts of the substrate take up a significant portion of the area of the top metal layer of the substrate directly below each flip-chip device, which limits space available in the top metal layer of the substrate to route traces between contacts.

This space constraint can be exacerbated by improvements in the flip-chip device technology, which often call for more interconnections to improve signaling rates, power, etc. This increase in interconnections requires more contacts on the top metal layer of the substrate as well as more traces to provide conductive paths to the contacts. Traces that cannot be routed in the top metal layer are routed through lower metal layers, which increases the cost of the substrate, the manufacturing complexity of the substrate, and the thickness of the substrate. Additionally, traces routed through lower metal layers are often longer than traces routed in higher metal layers resulting in decreased signaling performance. Accordingly, a problem facing certain integrated device designers and manufacturers is how to route conductive paths in a manner that provides desired signaling performance while also addressing other packaging concerns, such as cost, manufacturing complexity, manufacturing yield, and thickness.

Particular aspects disclosed herein provide solutions to the above problem as well as additional technical benefits by using a substrate that includes first device contacts on a first metal layer and second device contacts on a second metal layer that is over the first metal layer in a portion of the substrate. The second device contacts are electrically connected by vias to underlying via pads in the first metal layer. The via pads are smaller than their corresponding second device contacts. As a result, traces to interconnect various ones of the first device contacts and second device contacts can be routed through a shadow of the second device contacts. Put another way, the first metal layer can route more traces between adjacent via pads than could be routed between adjacent second device contacts.

Some aspects disclosed herein provide techniques for improved fabrication processes for packaged electronic devices having IC devices in a side-by-side arrangement. In such aspects, fabrication of a packaged electronic device may include depositing one or more solder resist layer(s) in multiple regions of the substrate. The solder resist layer(s) in the first region define a recess in which the first device contacts are disposed and the solder resist layer(s) in the second region provide an intervening layer between the via pads and the second device contacts. Depositing the solder resist layer(s) across an entirety (e.g., in multiple regions) of the substrate results in the packaged electronic device having a substantially uniform height and reduces cost and complexity of the fabrication process as compared to other fabrication processes that deposit dielectric layer(s), such as photo-imageable dielectric (PID) layer(s), only in the second region to form a plateau that has a larger height than the substrate in the first region.

Further, while adding the second metal layer slightly increases the thickness of the substrate in one region, or adding the solder resist layer(s) slightly increases the thickness of the substrate in multiple (e.g., all) regions, the additional space for routing traces can enable omission of lower metal layers that would otherwise be used for routing traces, leading to a net decrease in the number of metal layers and the overall thickness of the substrate. As a specific example, certain processor and memory systems use a substrate that includes five metal layers (e.g., two shield layers and three trace routing layers) to route double data rate (DDR) connections between a processor die and a memory die; however, aspects disclosed herein can be used to form the same DDR connections using as few as three metal layers (e.g., one shield layer and two trace routing layers), resulting in a reduction in layer count and thickness of the substrate.

Further, traces routed in the first metal layer are generally shorter than the traces would be if they were routed through lower metal layers. Shorter traces provide improved signal integrity and improved power integrity. Thus, the device-to-device trace distance reduction provided by the disclosed aspects improves performance of the devices.

Shortening the traces and reducing the count of metal layers also has the benefit of reducing the length of power interconnects to one or more of the devices. Reducing the power interconnect length decreases inductive and resistive losses of the traces and provides improved power distribution network performance.

In some implementations, the additional space available for routing traces on the first metal layer reduces routing constraints for breakout traces sufficiently to enable the devices to be positioned closer together on the substrate. In such implementations, the lateral dimensions (e.g., length and width) of the substrate can be reduced due to closer device-to-device distances. Thus, aspects disclosed herein can be used to reduce overall dimensions of a packaged electronic device due to reduction in lateral dimensions of the substrate and reduction in substrate thickness. Additionally, some aspects disclosed herein reduce cost and complexity of fabrication as compared to other packaged electronic devices with IC devices in a side-by-side arrangement on a substrate having non-uniform height.

Exemplary Device with Side-by-Side IC Devices

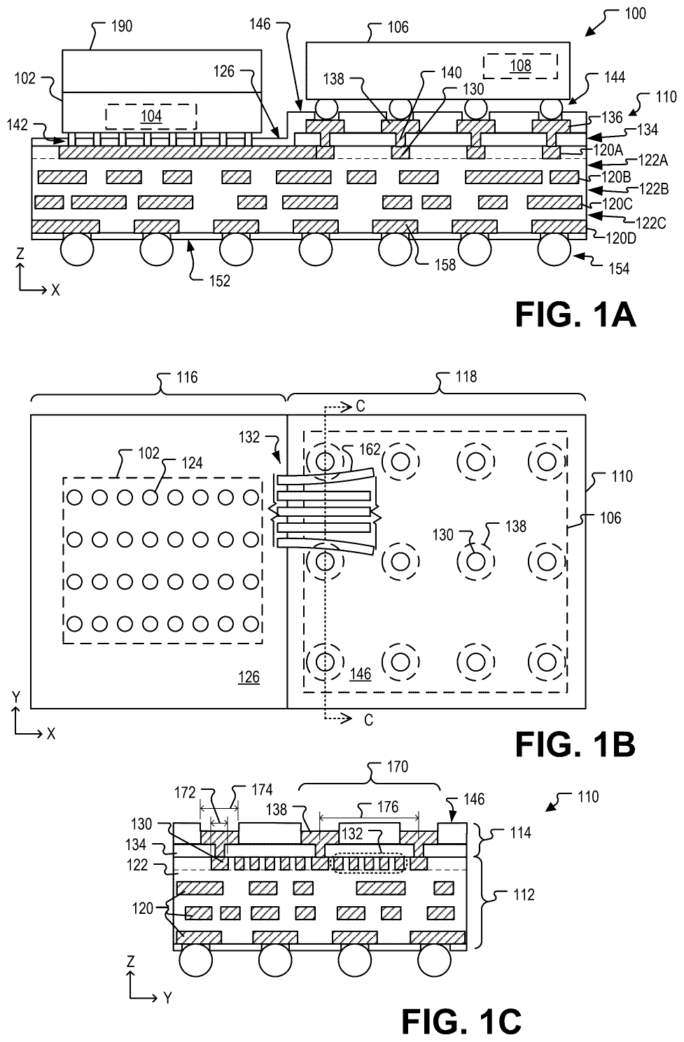

FIGS. 1A-1C illustrate various schematic views of an exemplary device 100. In particular, FIG. 1A illustrates a schematic longitudinal cross-sectional profile view of the device 100, FIG. 1B illustrates a partial schematic plan view of the device 100, and FIG. 1C illustrates a schematic transverse cross-section view along a cut line CC of FIG. 1B. In the view illustrated in FIG. 1A, the device 100 includes a substrate 110, a first integrated circuit (IC) device 102, and a second IC device 106. The plan view of FIG. 1B illustrates aspects of a top metal layer of the substrate 110 in solid lines and illustrates projections of features of other layers and components of the device 100 in dashed lines. The first IC device 102 and the second IC device 106 are omitted from FIG. 1C. FIGS. 1A-1C are each annotated with X-, Y-, and/or Z-axes to facilitate recognition of the orientation illustrated in each view.

The first IC device 102 includes circuitry 104, such as passive components (e.g., inductors, transistors, interconnects) and/or a plurality of transistors arranged to form logic cells, memory cells, amplifiers, switches, or other circuitry components. Further, the second IC device 106 includes circuitry 108, such as passive components (e.g., inductors, transistors, interconnects) and/or a plurality of transistors arranged to form logic cells, memory cells, amplifiers, switches, or other circuitry components. In some aspects, the first IC device 102 is a semiconductor die, a chiplet, a discrete component, or a surface-mountable package, and the second IC device 106 is a second semiconductor die, a chiplet, a discrete component, or a surface-mountable package. In some implementations, the first IC device 102, the second IC device 106, or both, include a plurality of dies (e.g., two or more stacked chiplets). The integrated circuitry of each of the IC devices 102, 106 can include a plurality of transistors and/or other circuit elements arranged and interconnected to form logic cells, memory cells, etc. Components of the integrated circuitry can be formed in and/or over a semiconductor substrate. Different implementations can use different types of transistors, such as a field effect transistor (FET), planar FET, finFET, a gate all around FET, or mixtures of transistor types. In some implementations, a front end of line (FEOL) process may be used to fabricate the integrated circuitry in and/or over the semiconductor substrate.

The substrate 110 is configured to electrically connect one or more circuit components of the circuitry 104 to one or more circuit components of the circuitry 108. For example, the first IC device 102 is connected to contacts 124 of the substrate 110 via interconnects 142 (e.g., an array of interconnects), and the second IC device 106 is connected to contacts 138 of the substrate 110 via interconnects 144. The substrate 110 includes a plurality of traces 132 electrically connecting respective ones of the contacts 124 and respective ones of the contacts 138 to provide conductive paths therebetween. To illustrate, the circuitry 104 can include one or more processors (e.g., the first IC device 102 can include a system-on-a-chip device), and the circuitry 108 can include one or more memory cells (e.g., the second IC device 106 can include a dynamic random access memory device), and the processor(s) can access the memory cells via conductive paths through the substrate 110. The substrate 110 can also provide conductive paths to external devices. For example, the substrate 110 includes contacts 158 (e.g., external contacts of the device 100) that are electrically connected, through the metal layers 120, to the devices 102, 106 (and possibly other devices). The contacts 158 are configured to provide off-package connections to other devices via an array of interconnects 154.

The substrate 110 includes a first layer stack 112 (annotated in FIG. 1C) that includes multiple metal layers 120 interspersed with multiple dielectric layers 122. For example, the metal layers 120 in FIG. 1A include a metal layer 120A, a metal layer 120B, a metal layer 120C, and a metal layer 120D. Although FIG. 1A illustrates the first layer stack 112 including four metal layers 120, in other implementations, the first layer stack 112 includes more than four or fewer than four metal layers 120. FIG. 1A also illustrates the dielectric layers 122 as including a dielectric layer 122A, a dielectric layer 122B, and a dielectric layer 122C. The count of dielectric layers 122 will be different if the count of metal layers 120 is different.

The first layer stack 112 has a first side 126 and a second side 152 opposite the first side 126. Starting from the first side 126, the metal layer 120A (e.g., an M1 layer) of the substrate 110 includes contacts 124 disposed in a first region 116 (annotated in FIG. 1B). The contacts 124 are configured to electrically connect to the first IC device 102 via the interconnects 142 (illustrated as pillar bumps or microbumps in FIG. 1A).

The metal layer 120A also includes via pads 130 disposed in a second region 118 that is offset along a first direction (e.g., along the X-axis) from the first region 116. As described further below, the via pads 130 are configured to form a portion of the electrical connections to the second IC device 106.

The metal layer 120A also includes traces 132 electrically connected to the contacts 124 and to the via pads 130. Only a portion of each of the traces 132 is illustrated in FIG. 1B to simplify the diagram while highlighting particular aspects of routing of the traces 132. In particular, one or more of the traces 132 extend between a pair 170 of adjacent via pads 130. For example, FIG. 1B illustrates five traces 132 between a pair of adjacent via pads 130. The count of traces 132 between adjacent pairs of via pads 130 can be different for different pairs of adjacent via pads 130. Additionally, or alternatively, the count of traces 132 between adjacent pairs of via pads 130 can be different for different implementations.

The substrate 110 also includes a second layer stack 114 (annotated in FIG. 1C). The second layer stack 114 is coupled to the second region 118 of the metal layer 120A and defines a plateau 146 (e.g., a step up) relative to the first region 116. The second layer stack 114 includes a dielectric layer 134, a metal layer 136 coupled to the dielectric layer 134 opposite the first layer stack 112, and conductive vias 140.

The metal layer 136 defines contacts 138 configured to electrically connect to the second IC device 106. For example, in FIG. 1A, the second IC device 106 is electrically connected to the contacts 138 by the interconnects 144 (e.g., an array of interconnects). The conductive vias 140 extend between respective ones of the via pads 130 and the contacts 138 to electrically connect the contacts 138 to the via pads 130.

The contacts 138 are positioned to align with contacts of the second IC device 106 and are sized appropriately for coupling with the interconnects 144. For example, when the second IC device 106 includes DRAM, the contacts 138 are typically circular with a diameter of about 280 microns and a pitch of about 400 microns, which leaves about 120 microns between adjacent pairs of contacts 138. The via pads 130 are positioned to align with the contacts 138 and are sized smaller than the contacts 138. For example, in one implementation, the via pads 130 have a pitch of 400 microns (e.g., the same pitch as contacts of the second IC device 106) and have a diameter of 75 microns, which leaves about 280 microns between adjacent via pads 130. More generally, a pitch 176 of the via pads 130 is approximately equal to a pitch of the contacts 138, and the contacts 138 have a characteristic dimension 174 (e.g., diameter for circular contacts) that is greater than a characteristic dimension 172 (e.g., diameter for circular pads) of the via pads 130. For example, the characteristic dimension of the contacts 138 may be one and a half to five times (e.g., at least three times) the characteristic dimension of the via pads 130.

As a result, of the substantially equal pitch of the contacts 138 and the via pads 130, and the larger characteristic dimension of the contacts 138 than the via pads 130, a characteristic spacing between adjacent via pads 130 is greater than a characteristic spacing between adjacent contacts 138. For example, the characteristic spacing between adjacent via pads 130 may be greater than the characteristic spacing between adjacent contacts 138 by a factor of one and a half to three (e.g., at least a factor of two). The additional space between the via pads 130 provides more room for routing traces 132 than would be available for routing traces between the contacts 138. For example, as illustrated in FIG. 1B, in some implementations, one or more of the traces 132, e.g., a trace 162, can intersect a shadow of one or more of the contacts 138. In this context, the “shadow” of a component refers to a vertical projection of the component onto a layer above or below the component. For example, the shadow of a contact would include an area of a layer below the contact that is covered by the contact when the contact is viewed from above.

In the example illustrated in FIG. 1A, the device 100 includes an optional heat sink 190 coupled to an upper surface of the first IC device 102. Optionally, the device 100 can also, or alternatively, include a heat sink coupled to an upper surface of the second IC device 106. When present, the heat sink 190 facilitates dissipation of heat generated during operation of an IC device to which it is coupled.

The exemplary device 100 illustrated in FIGS. 1A-1C solves the problems described above regarding routing conductive paths in a manner that provides desired signaling performance while also addressing other packaging concerns, such as cost, manufacturing complexity, and thickness. For example, the metal layer 120A of the first layer stack 112 can route more traces between adjacent via pads 130 than could be routed between adjacent contacts 138 which reduces the length of such traces 132 relative to traces that are routed through lower metal layers (e.g., metal layers 120B and below). Further, by enabling routing of more traces 132 on the metal layer 120A, the number of traces that need to be routed through the lower metal layers is reduced, which may enable reducing the number of metal layers of the first layer stack 112, resulting in decreased thickness and cost of the substrate 110.

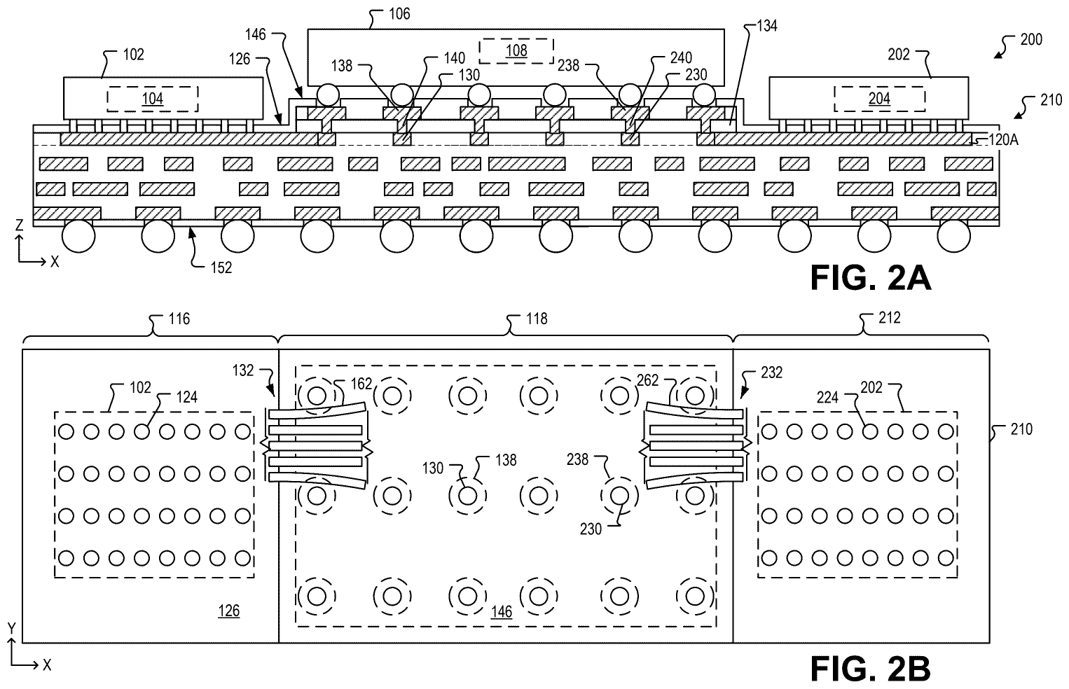

FIGS. 2A and 2B illustrate schematic views of another exemplary device 200 similar to the device 100 of FIGS. 1A-1C. In particular, FIG. 2A illustrates a schematic longitudinal cross-sectional profile view of the device 200, and FIG. 2B illustrates a partial schematic plan view of the device 200. No transverse cross-section of the device 200 is shown since it would be the same as the transverse cross-section view of FIG. 1C.

In FIGS. 2A and 2B, the device 200 includes a substrate 210, the first IC device 102, the second IC device 106, and a third IC device 202. The first and second IC devices 102, 106 are the same as described with reference to FIGS. 1A-1C. The third IC device 202 is another example of the first IC device 102, is another example of the second IC device 106, or includes additional circuitry 204 configured to interact with the circuitry 104 of the first IC device 102, the circuitry 108 of the second IC device 106, or both.

The metal layer 120A of the substrate 210 includes the contacts 124 disposed in the first region 116, the via pads 130 disposed in the second region 118 (e.g., as in FIGS. 1A-1C), via pads 230 disposed in the second region 118, and contacts 224 disposed in a third region 212. In the example illustrated, the second region 118 is between the first region 116 and the third region 212, and the third region 212 is at the same level as (e.g., substantially coplanar with) the first region 116. The contacts 224 are configured to electrically connect to the third IC device 202 via interconnects (e.g., solder balls, solder bumps, pillar bumps, etc.). The via pads 230 are electrically connected to contacts 238 by vias 240 that extend through the dielectric layer 134. The contacts 238 are configured to electrically connect to corresponding contacts of the second IC device 106. Alternatively, in some implementations, the second region 118 can include more than one second IC device 106, in which case the contacts 238 may be configured to electrically connect to a different second IC device than the contacts 138.

The metal layer 120A of FIGS. 2A and 2B also includes the traces 132 and traces 232. The traces 132 are as described with reference to FIGS. 1A-1C. The traces 232 are similar to the traces 132 except that the traces 232 are configured to provide conductive paths between various ones of the contacts 238 and various ones of the contacts 224. For example, in some implementations, the circuitry 104 of the first IC device 102 includes one or more processor cores, the circuitry 204 of the third IC device 202 includes one or more processor cores, and the circuitry 108 of the second IC device 106 includes one or more memory cells accessible to the circuitry 104 via the traces 132 and accessible to the circuitry 204 via the traces 232.

As described with reference to FIGS. 1A-1C, the via pads 130 have a characteristic dimension that is smaller than a corresponding characteristic dimension of the contacts 138. Likewise, the via pads 230 have a characteristic dimension that is smaller than a corresponding characteristic dimension of the contacts 238. Further, the via pads 230 have substantially the same pitch as the contacts 238. As a result, there is more space between the via pads 230 to route the traces 232 than there would be to route the traces 232 between the contacts 238. For example, one or more of the traces 232 (e.g., a trace 262) can extend between a pair of the via pads 230 and intersect a shadow of one or more of the contacts 238.

In some implementations of the device 200, the substrate 210 can also include conductive paths to enable signaling between the first IC device 102 and the third IC device 202. For example, in such implementations, at least one metal layer of the multiple metal layers 120 of the substrate 210 can include traces configured to electrically connect the first IC device 102 and the third IC device 202.

In addition to the benefits described above, the configuration of the device 200 illustrated in FIGS. 2A and 2B can also provide additional benefits. For example, spacing the device 102 and the device 202 on opposite sides of the device 106 reduces signal interference between signals from the devices 102 and 202. To illustrate, when the device 106 includes a DRAM device and the devices 102, 202 include processor cores that access the DRAM device via traces 132 and 232, respectively, signals on the traces 132 do not interfere with signals on the traces 232 due to the large space therebetween.

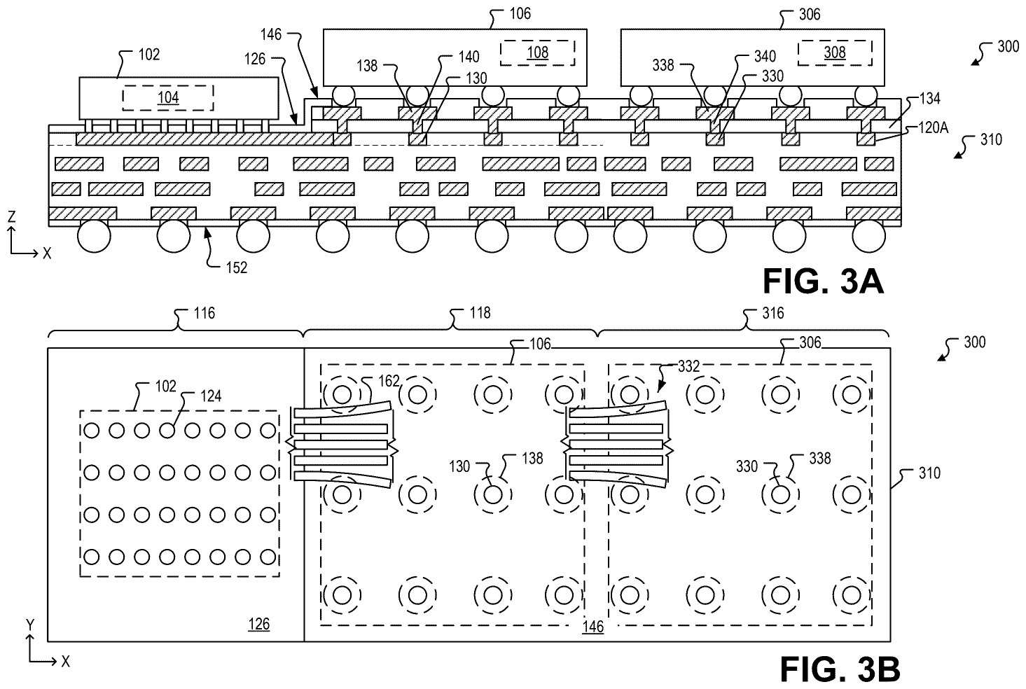

FIGS. 3A and 3B illustrate schematic views of another exemplary device 300 similar to the device 100 of FIGS. 1A-1C. In particular, FIG. 3A illustrates a schematic longitudinal cross-sectional profile view of the device 300, and FIG. 3B illustrates a partial schematic plan view of the device 300. No transverse cross-section of the device 300 is shown since it would be the same as the transverse cross-section view of FIG. 1C.

In FIGS. 3A and 3B, the device 300 includes a substrate 310, the first IC device 102, the second IC device 106, and a third IC device 306. The first and second IC devices 102, 106 are the same as described with reference to FIGS. 1A-1C. The third IC device 306 is another example of the first IC device 102, is another example of the second IC device 106, or includes additional circuitry 308 configured to interact with the circuitry 104 of the first IC device 102, the circuitry 108 of the second IC device 106, or both.

The metal layer 120A of the substrate 310 includes the contacts 124 disposed in the first region 116, the via pads 130 disposed in the second region 118 (e.g., as in FIGS. 1A-1C), and via pads 330 disposed in a third region 316. In the example illustrated, the second region 118 is between the first region 116 and the third region 316. The via pads 330 are electrically connected to contacts 338 by vias 340 that extend through the dielectric layer 134. The contacts 338 are configured to electrically connect to corresponding contacts of the third IC device 306.

The metal layer 120A of FIGS. 3A and 3B includes the traces 132 and traces 332. The traces 132 are as described with reference to FIGS. 1A-1C. The traces 332 are similar to the traces 132 except that the traces 332 are configured to provide conductive paths between various ones of the contacts 338 and various ones of the contacts 124, the contacts 138, or both. In some implementations, one or more of the traces 332 can intersect a shadow of one of the contacts 338.

Although the device 200 and the device 300 have been illustrated separately, in some cases, a device can include aspects of the device 200 combined with aspects of the device 300. For example, the device 300 includes more than one IC device disposed on a highest surface (e.g. a plateau) of a top side of a substrate, and the device 200 includes more than one IC device on a lower surface of a top side of a substrate. In some cases, a device can include two or more IC devices disposed on the highest surface (e.g. a plateau) of a top side a substrate and two or more IC devices on a lower surface of the top side of a substrate.

In some implementations, two or more of the IC devices 102, 106, 202, and/or 306 include chiplets arranged and interconnected via a substrate, which can provide various benefits as compared to providing the same functional circuitry in one monolithic chip. For example, each chiplet is smaller than a monolithic die including all of the same functional circuit blocks would be. Since yield loss in IC manufacturing tends to increase as the die size increases, using smaller dies can reduce yield loss (i.e., increase yield) of the IC manufacturing process. Another benefit is that the chiplets can be fabricated in different locations and/or by different manufacturers, and in some cases, using different fabrication technologies (e.g., different fabrication technology nodes). As an example, one chiplet-based integrated device (e.g., the IC device 102) can include components (e.g., interconnects, transistors, etc.) that have a first minimum size, and another chiplet-based integrated device (e.g., the second IC device 106) can include components (e.g., interconnects, transistors, etc.) that have a second minimum size, where the second minimum size is greater than the first minimum size. In contrast, all of the circuitry of a monolithic die is fabricated using the same fabrication technologies and equipment. As a result, when manufacturing a monolithic die, the entire die may be subject to the tightest manufacturing constraint of the most complex component of the monolithic die. In contrast, when using chiplets, different chiplets can be manufactured using different fabrication technologies (e.g., different fabrication technology nodes), and only the chiplet or chiplets that include the most complex components are subjected to the tightest manufacturing constraints. In this arrangement, chiplets fabricated using less expensive and/or higher yield fabrication technologies can be integrated with chiplets fabricated using more expensive and/or lower yield fabrication technologies to form a device (e.g., any of the devices 100, 200, or 300), resulting in overall savings. Still further, in some cases, as technology improves, the design of a chiplet can be changed.

Any of the devices 100, 200, or 300 can be integrated with or included within a wide variety of other devices. For example, a device that includes one or more of the devices 100, 200, or 300 disclosed herein can include components such as a power management integrated circuit (PMIC), an application processor, a modem, a radio frequency (RF) device, a passive device, a filter, a capacitor, an inductor, a transmitter, a receiver, a gallium arsenide (GaAs) based integrated device, a surface acoustic wave (SAW) filter, a bulk acoustic wave (BAW) filter, a light emitting diode (LED) integrated device, a silicon (Si) based integrated device, a silicon carbide (SiC) based integrated device, a memory, power management processor, and/or combinations thereof. In such devices, the devices 100, 200, or 300 (or one or more of the IC devices thereof) can operate as any of these components (or a combination of these components) that includes active circuitry.

Exemplary Sequence for Fabricating a Device with Side-by-Side IC Devices

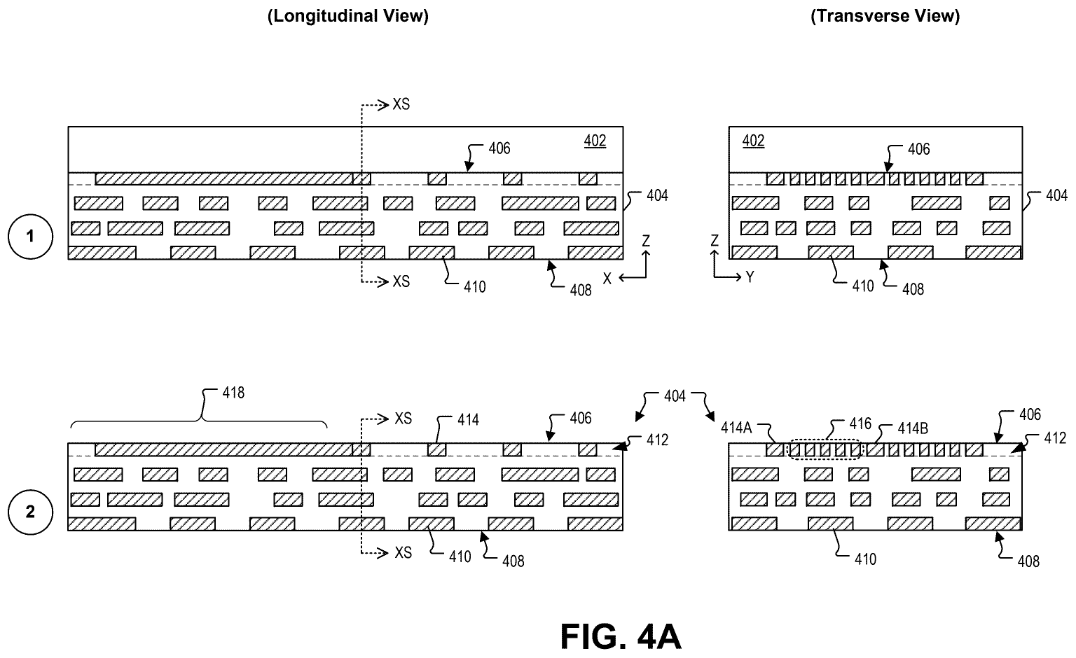

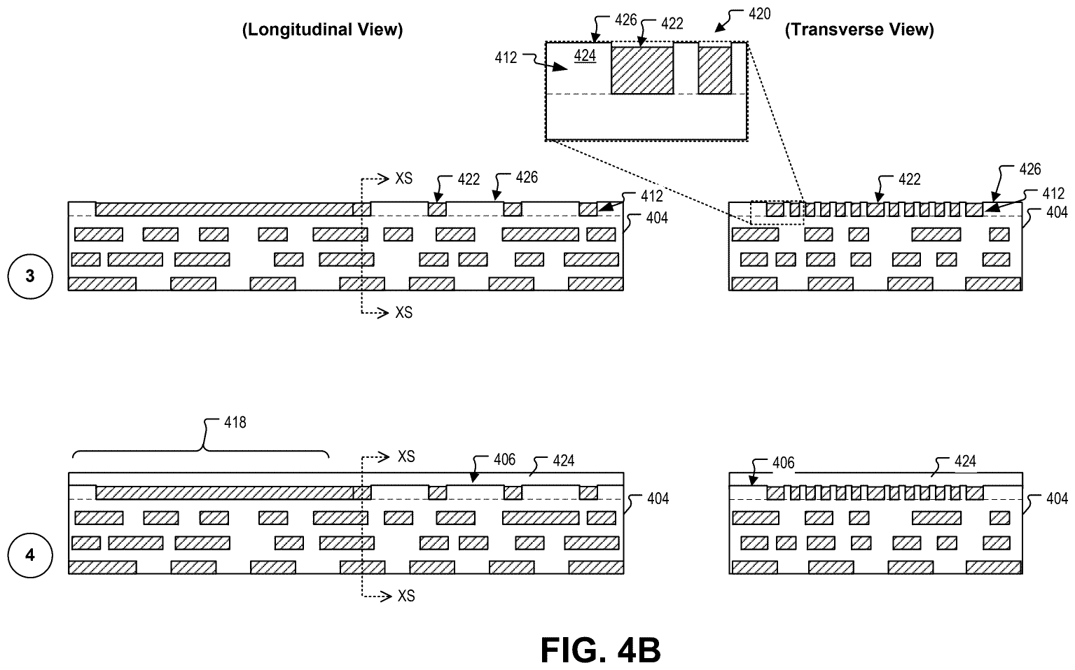

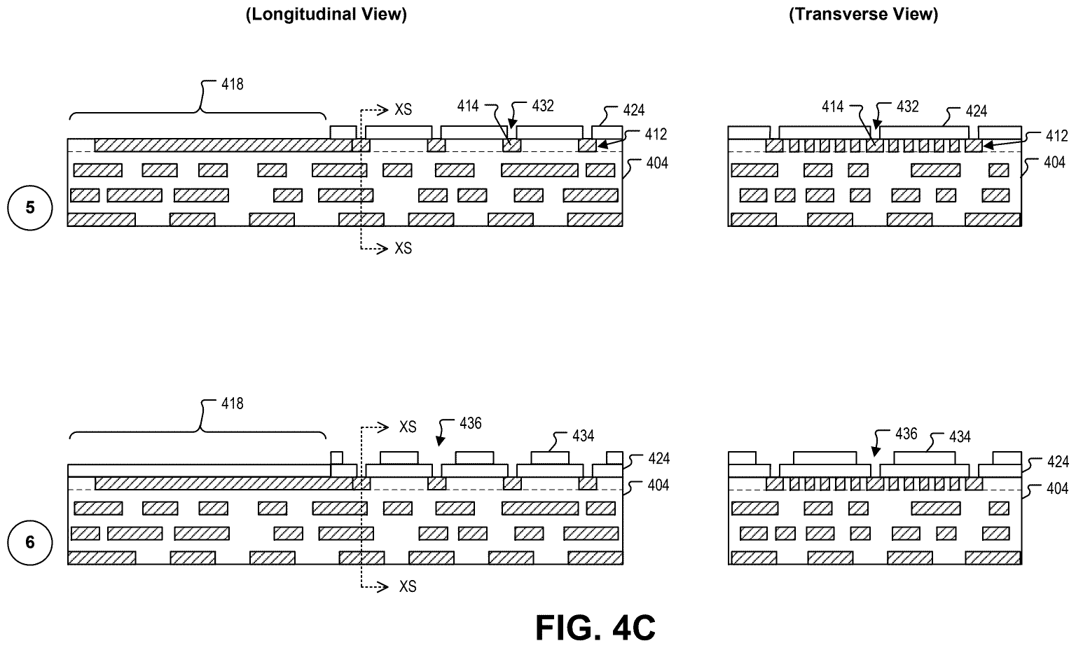

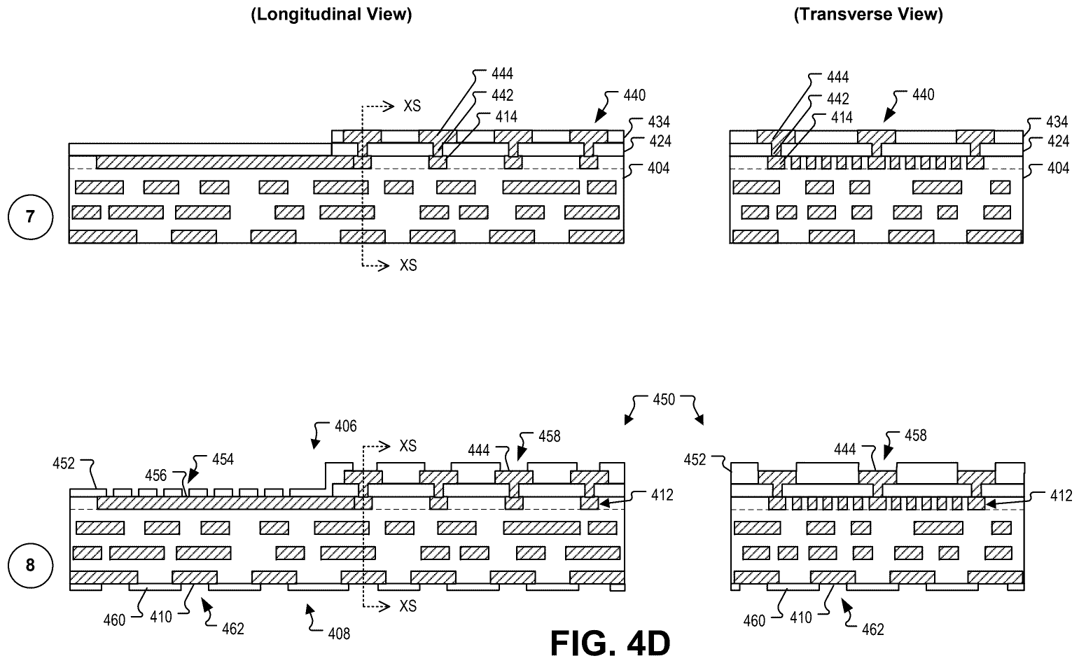

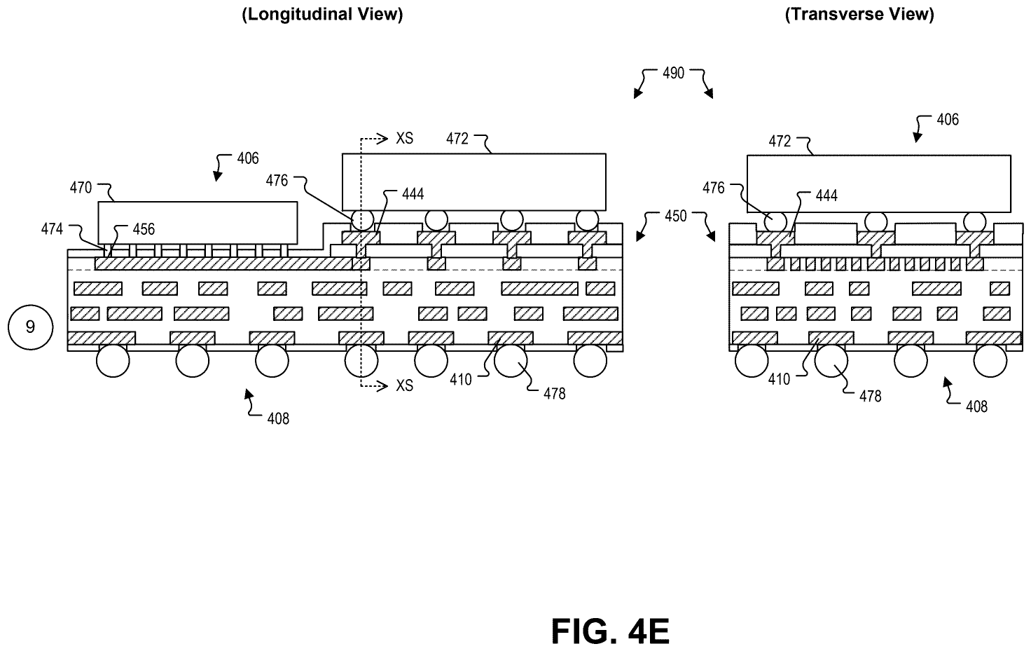

In some implementations, fabricating a device (e.g., any of the devices 100, 200, or 300 of FIGS. 1A-3B) includes several processes. FIGS. 4A-4E, together, illustrate an exemplary sequence for providing or fabricating that includes multiple IC devices interconnected in a side-by-side arrangement, as described with reference to any of FIGS. 1A-3B.

In the example illustrated in FIGS. 4A-4E, various stages during fabrication of a device are shown, where each stage represents a state after performance of one or more fabrication operations. In some implementations, the order of performance of various operations can be changed or modified. In some implementations, one or more of the processes may be replaced or substituted without departing from the scope of the disclosure. In the following description, reference is made to various illustrative stages of the sequence, which are numbered (using circled numbers) in FIGS. 4A-4E. Each of the various stages of the sequence of FIGS. 4A-4E is illustrated with a schematic longitudinal cross-sectional profile view (“longitudinal view”) and a corresponding schematic transverse cross-section view (“transverse view”) along a cut line XS shown in the longitudinal view. The sequence of FIGS. 4A-4E illustrates stages of a sequence for fabricating a device that includes two IC devices interconnected in a side-by-side arrangement on a substrate; however, the sequence can be used to form devices with more than two IC devices, such as the device 200 of FIGS. 2A and 2B, the device 300 of FIGS. 3A and 3B, or a combination thereof.

Stage 1 of FIG. 4A illustrates a state after formation of a first layer stack 404 on a carrier substrate 402. The first layer stack 404 includes or corresponds to the first layer stack 112 of FIG. 1C. For example, the first layer stack 404 includes multiple metal layers (e.g., metal layers 120 of FIGS. 1A-1C) interspersed with multiple dielectric layers (e.g., dielectric layers 122 of FIGS. 1A-1C).

In the implementation illustrated in FIG. 4A, a first side 406 of the first layer stack 404 is adjacent to the carrier substrate 402, and a second side 408 of the first layer stack 404 is opposite the carrier substrate 402. In this implementation, the second side 408 includes a bottom metal layer of a substrate that is being formed (e.g., substrate 450 of FIG. 4E), and the bottom metal layer is patterned to form contacts 410. For example, the bottom metal layer may correspond to or include the metal layer 120D of FIG. 1A. The contacts 410 disposed on the second side 408 may correspond to or include the contacts 158 of FIG. 1A. In other implementations, the second side 408 is formed adjacent to the carrier substrate 402, leaving the first side 406 exposed at Stage 1.

The first layer stack 404 can be formed on the carrier substrate 402 using lamination techniques, such as patterning metal layers, application of dielectric layers, and formation of vias interconnecting various metal layers through the dielectric layers. In some implementations, deposition techniques can be used instead of or along with lamination techniques to form the first layer stack 404 on the carrier substrate 402. For example, deposition techniques can include deposition of metal layers, deposition of dielectric layers, and/or deposition of conductive vias.

Stage 2 illustrates a state of the first layer stack 404 after the carrier substrate 402 is removed. Removal of the carrier substrate 402, in the implementation illustrated, reveals the first side 406 of the first layer stack 404. The first side 406 includes a top metal layer 412 of the first layer stack 404. The top metal layer 412 is patterned to define one or more via pads 414 and one or more traces 416 that extend between a pair of adjacent via pads (e.g., a via pad 414A and a via pad 414B). The top metal layer 412 is also patterned, in a region 418, to define contacts that are configured to electrically connect to a first IC device (e.g., IC device 470 shown in FIG. 4E).

Stage 3 of FIG. 4B illustrates a state of the first layer stack 404 after one or more etching operations are performed. The etching operation(s) cause an upper surface 422 of the top metal layer 412 to be recessed below an upper surface 426 of a dielectric layer 424 on the first side 406 (as best seen in inset view 420). For example, one or more metal etching operations can be used to etch the upper surface 422 of the top metal layer 412.

Stage 4 of FIG. 4B illustrates a state of the first layer stack 404 after formation of a dielectric layer 424 on the first side 406 of the first layer stack 404. For example, the dielectric layer 424 can include a dry film (e.g., a photo-imageable dielectric film) that is laminated onto the first side 406. In a particular aspect, the dielectric layer 424 includes or corresponds to the dielectric layer 134 of FIGS. 1A-3A. Although FIG. 4B illustrates the dielectric layer 424 covering the region 418, in some implementations, the dielectric layer 424 is omitted from the region 418.

Stage 5 of FIG. 4C illustrates a state after patterning of the dielectric layer 424. The dielectric layer 424 is patterned to define openings 432 exposing portions of via pads 414. Additionally, if the dielectric layer 424 is present in the region 418, patterning the dielectric layer 424 includes removing a portion of the dielectric layer 424 present in the region 418 to expose structures of the top metal layer 412 in the region 418. In implementations in which the dielectric layer 424 includes a photo-imageable dielectric film, patterning the dielectric layer 424 includes exposing portions of the dielectric layer 424 to light to define a pattern (or a reverse pattern) and developing the dielectric layer 424 to remove uncured portions of the dielectric layer 424.

Stage 6 illustrates a state after formation and patterning of a resist layer 434. The resist layer 434 is patterned to define openings 436. As explained further with reference to Stage 7 of FIG. 4D, the openings 436 are positioned and sized to guide formation of structures that include or correspond to contacts for electrical connection to an IC device, such as IC device 472 shown in FIG. 4E. The openings 436 are generally concentric with the openings 432 and sized larger than the openings 432.

Stage 7 of FIG. 4D illustrates a state after formation of conductive vias 442 and contacts 444. Each of the conductive vias 442 is electrically connected to a respective one of the via pads 414 and electrically connected to a respective contact 444. In the example illustrated, the contacts 444 and conductive vias 442 are formed as unitary structures (e.g., structures 440). For example, one or more metal deposition operations, guided by the openings 436 in the resist layer 434 and the openings 432 in the dielectric layer 424, can be used to form the structures 440.

Stage 8 illustrates a state after removal of the resist layer 434 and formation and patterning of a solder resist layer 452 on the first side 406, and formation and patterning of a solder resist layer 460 on the second side 408. The solder resist layer 452 is patterned to include openings 454 that provide access to contacts 456 of the top metal layer 412 that are configured to be electrically connected to an IC device (e.g., the IC device 470 of FIG. 4E). The solder resist layer 452 is also patterned to include openings 458 that provide access to the contacts 444 that are configured to be electrically connected to another IC device (e.g., the IC device 472 of FIG. 4E). The solder resist layer 460 is patterned to include openings 462 that provide access to the contacts 410 that are configured to provide off-device conductive pathways. Formation of a substrate 450 is complete at Stage 8 of FIG. 4D.

Formation of a device 490 is complete at Stage 9 of FIG. 4E. Stage 9 illustrates a state after an IC device 470 and an IC device 472 are attached to the substrate 450. The IC device 470 is connected, via interconnects 474 to the contacts 456. The IC device 470 includes or corresponds to the IC device 102 of any of FIGS. 1A-3B, and the interconnects 474 include or correspond to the interconnects 142 of FIG. 1A, which are electrically connected to the contacts 124 (illustrated, for example, in FIG. 1B). The IC device 472 is connected, via interconnects 476 to the contacts 444. The IC device 472 includes or corresponds to the IC device 106 of any of FIGS. 1A-3B, and the interconnects 476 include or correspond to the interconnects 144 of FIG. 1A. In the example illustrated in FIG. 4E, the device 490 also includes interconnects 478 (e.g., an array of solder balls) electrically connected to the contacts 410 on the second side 408.

Although the device 490 is illustrated as including two IC devices 470, 472 coupled to a substrate 450, as described with reference to FIGS. 2A-3B, more than two IC devices can be coupled to the substrate 450. For example, the device 490 can include more than one IC device disposed on a highest surface (e.g., a plateau) of the first side 406 of the substrate 450 as in the exemplary device 300 of FIGS. 3A-3B. As another example, the device 490 can include more than one IC device disposed on a lower surface of the first side 406 of the substrate 450 as in the exemplary device 200 of FIGS. 2A-2B.

The device 490 solves problems related to routing conductive paths in a manner that provides desired signaling performance while also addressing other packaging concerns, such as cost, manufacturing complexity, and thickness. For example, the top metal layer 412 of the first layer stack 404 can route more traces 416 between adjacent via pads 414 (annotated in FIG. 4A) than could be routed between adjacent contacts 444 which reduces the length of such traces 416 relative to traces that are routed through lower metal layers of the first layer stack 404. Further, by enabling routing of more traces 416 on the top metal layer 412 of the first layer stack 404, the number of traces that need to be routed through the lower metal layers is reduced, which may enable reducing the number of metal layers of the first layer stack 404, resulting in decreased thickness and cost of the substrate 450.

Exemplary Device with Side-by-Side IC Devices on a Substrate that Includes Solder Resist Layer(s)

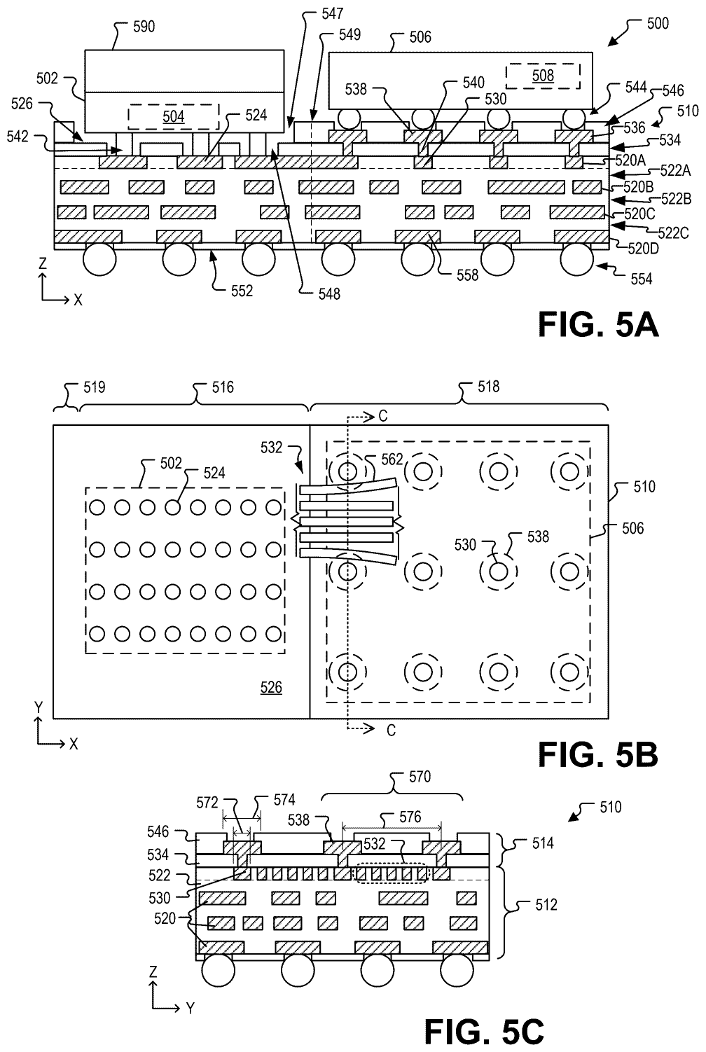

FIGS. 5A-5C illustrate various schematic views of an exemplary device 500. In particular, FIG. 5A illustrates a schematic longitudinal cross-sectional profile view of the device 500, FIG. 5B illustrates a partial schematic plan view of the device 500, and FIG. 5C illustrates a schematic transverse cross-section view along a cut line CC of FIG. 5B. In the view illustrated in FIG. 5A, the device 500 includes a substrate 510, a first IC device 502, and a second IC device 506. The plan view of FIG. 5B illustrates aspects of a top metal layer of the substrate 510 in solid lines and illustrates projections of features of other layers and components of the device 500 in dashed lines. The first IC device 502 and the second IC device 506 are omitted from FIG. 5C. FIGS. 5A-5C are each annotated with X-, Y-, and/or Z-axes to facilitate recognition of the orientation illustrated in each view.

The first IC device 502 includes circuitry 504, such as passive components (e.g., inductors, transistors, interconnects) and/or a plurality of transistors arranged to form logic cells, memory cells, amplifiers, switches, or other circuitry components. Further, the second IC device 506 includes circuitry 508, such as passive components (e.g., inductors, transistors, interconnects) and/or a plurality of transistors arranged to form logic cells, memory cells, amplifiers, switches, or other circuitry components. In some aspects, the first IC device 502 is a semiconductor die, a chiplet, a discrete component, or a surface-mountable package, and the second IC device 506 is a second semiconductor die, a chiplet, a discrete component, or a surface-mountable package. In some implementations, the first IC device 502, the second IC device 506, or both, include a plurality of dies (e.g., two or more stacked chiplets). The integrated circuitry of each of the IC devices 502, 506 can include a plurality of transistors and/or other circuit elements arranged and interconnected to form logic cells, memory cells, etc. Components of the integrated circuitry can be formed in and/or over a semiconductor substrate. Different implementations can use different types of transistors, such as a FET, planar FET, finFET, a gate all around FET, or mixtures of transistor types. In some implementations, a FEOL process may be used to fabricate the integrated circuitry in and/or over the semiconductor substrate.

The substrate 510 is configured to electrically connect one or more circuit components of the circuitry 504 to one or more circuit components of the circuitry 508. For example, the first IC device 502 is connected to contacts 524 of the substrate 510 via interconnects 542 (e.g., an array of interconnects), and the second IC device 506 is connected to contacts 538 of the substrate 510 via interconnects 544. The substrate 510 includes a plurality of traces 532 electrically connecting respective ones of the contacts 524 and respective ones of the contacts 538 to provide conductive paths therebetween. To illustrate, the circuitry 504 can include one or more processors (e.g., the first IC device 502 can include a system-on-a-chip device), and the circuitry 508 can include one or more memory cells (e.g., the second IC device 506 can include a dynamic random access memory (DRAM) device), and the processor(s) can access the memory cells via conductive paths through the substrate 510. The substrate 510 can also provide conductive paths to external devices. For example, the substrate 510 includes contacts 558 (e.g., external contacts of the device 500) that are electrically connected, through the metal layers 520, to the IC devices 502, 506 (and possibly other devices). The contacts 558 are configured to provide off-package connections to other devices via an array of interconnects 554.

The substrate 510 includes a first layer stack 512 (annotated in FIG. 5C) that includes multiple metal layers 520 interspersed with multiple dielectric layers 522. For example, the metal layers 520 in FIG. 5A include a metal layer 520A, a metal layer 520B, a metal layer 520C, and a metal layer 520D. Although FIG. 5A illustrates the first layer stack 512 including four metal layers 520, in other implementations, the first layer stack 512 includes more than four or fewer than four metal layers 520. FIG. 5A also illustrates the dielectric layers 522 as including a dielectric layer 522A, a dielectric layer 522B, and a dielectric layer 522C. The count of dielectric layers 522 will be different if the count of metal layers 520 is different.

The first layer stack 512 has a first side 526 and a second side 552 opposite the first side 526. Starting from the first side 526, the metal layer 520A (e.g., an M1 layer) of the substrate 510 includes the contacts 524 disposed in a first region 516 (annotated in FIG. 5B). The contacts 524 are configured to electrically connect to the first IC device 502 via the interconnects 542 (illustrated as pillar bumps or microbumps in FIG. 5A).

The metal layer 520A also includes via pads 530 disposed in a second region 518 (annotated in FIG. 5B) that is offset along a first direction (e.g., along the X-axis) from the first region 516. As described further below, the via pads 530 are configured to form a portion of the electrical connections to the second IC device 506.

The metal layer 520A also includes traces 532 electrically connected to the contacts 524 and to the via pads 530. Only a portion of each of the traces 532 is illustrated in FIG. 5B to simplify the diagram while highlighting particular aspects of routing of the traces 532. In particular, one or more of the traces 532 extend between a pair 570 (annotated in FIG. 5C) of adjacent via pads 530. For example, FIG. 5B illustrates five traces 532 between a pair of adjacent via pads 530. In other implementations, the count of traces 532 between adjacent pairs of via pads 530 can be fewer than five or more than five (e.g., eight) traces. The count of traces 532 between adjacent pairs of via pads 530 can be different for different pairs of adjacent via pads 530. Additionally, or alternatively, the count of traces 532 between adjacent pairs of via pads 530 can be different for different implementations.

The substrate 510 also includes a second layer stack 514 (annotated in FIG. 5C). The second layer stack 514 is coupled to the second region 518 of the metal layer 520A. The second layer stack 514 includes a first solder resist layer 534, a metal layer 536 coupled to the first solder resist layer 534 opposite the first layer stack 512, and conductive vias 540. The first solder resist layer 534 is disposed on a surface that includes the metal layer 520A and the dielectric layer 522A and defines openings 548 to the contacts 524 and openings to the via pads 530 (which may be filled in to form the conductive vias 540). Although the second layer stack 514 is disposed in the second region 518, the first solder resist layer 534 is coupled to the above-described surface in multiple regions, such as across an entirety of the substrate 510. To illustrate, the first solder resist layer 534 is disposed in the first region 516, the second region 518, and a third region 519 (annotated in FIG. 5B) that is offset along a second direction (e.g., along the X-axis) from the first region 516. The second direction is opposite to the first direction in which the second region 518 is offset from the first region 516. The third region 519 may be along an edge of the device 500 or between the first IC device 502 and another IC device that is in a side-by-side arrangement in the second direction from the first IC device 502.

The substrate 510 also includes a second solder resist layer 546 disposed on the first solder resist layer 534 and at least a portion of the metal layer 536. The second solder resist layer 546 defines an opening 547 (e.g., a recess) in the first region 516 in which the openings 548 are located and the first IC device 502 is disposed. In the second region 518, the second solder resist layer 546 is disposed on at least a portion of the metal layer 536 and defines one or more openings in which the interconnects 544 are disposed. For example, portions of the second solder resist layer 546 may cover edge portions of contacts 538 defined by the metal layer 536. Additionally, portions of the second solder resist layer 546 are disposed on the first solder resist layer 534 across an entirety of the substrate 510. For example, a first portion of the second solder resist layer 546 is disposed on the first solder resist layer 534 in the first region 516, such as to one side (e.g., the left) of a notional border 549 between the first region 516 and the second region 518. As other examples, a second portion of the second solder resist layer 546 is disposed on the first solder resist layer 534 in the second region 518 (e.g., to an opposite side of the border 549) and a third portion of the second solder resist layer 546 is disposed on the first solder resist layer 534 in the third region 519. Depositing the first solder resist layer 534 and the second solder resist layer 546 across the substrate 510, instead of in a particular region, may result in a fabrication process having reduced complexity and cost, as further described herein. Although described as distinct solder resist layers, the first solder resist layer 534 and the second solder resist layer 546 may include the same material and be deposited using similar techniques, such that the layers may be referred to collectively as a single solder resist layer. Alternatively, the second solder resist layer 546 may include a different material or have different properties than the first solder resist layer 534.

The metal layer 536 defines contacts 538 configured to electrically connect to the second IC device 506. For example, in FIG. 5A, the second IC device 506 is electrically connected to the contacts 538 by the interconnects 544 (e.g., an array of interconnects). The conductive vias 540 extend between respective ones of the via pads 530 and the contacts 538 to electrically connect the contacts 538 to the via pads 530.

The contacts 538 are positioned to align with contacts of the second IC device 506 and are sized appropriately for coupling with the interconnects 544. For example, when the second IC device 506 includes DRAM, the contacts 538 are typically circular with a diameter of about 280 microns and a pitch of about 400 microns, which leaves about 120 microns between adjacent pairs of contacts 538. The via pads 530 are positioned to align with the contacts 538 and are sized smaller than the contacts 538. For example, in one implementation, the via pads 530 have a pitch of 400 microns (e.g., the same pitch as contacts of the second IC device 506) and have a diameter of 75 microns, which leaves about 280 microns between adjacent via pads 530. More generally, a pitch 576 of the via pads 530 is approximately equal to a pitch of the contacts 538, and the contacts 538 have a characteristic dimension 574 (e.g., diameter for circular contacts) that is greater than a characteristic dimension 572 (e.g., diameter for circular pads) of the via pads 530. For example, the characteristic dimension of the contacts 538 may be one and a half to five times (e.g., at least three times) the characteristic dimension of the via pads 530, such as the characteristic dimension of the contacts 538 being 270 μm and the characteristic dimension of the via pads 530 being 70 μm.

As a result, of the substantially equal pitch of the contacts 538 and the via pads 530, and the larger characteristic dimension of the contacts 538 than the via pads 530, a characteristic spacing between adjacent via pads 530 is greater than a characteristic spacing between adjacent contacts 538. For example, the characteristic spacing between adjacent via pads 530 may be greater than the characteristic spacing between adjacent contacts 538 by a factor of one and a half to three (e.g., at least a factor of two). The additional space between the via pads 530 provides more room for routing traces 532 than would be available for routing traces between the contacts 538. For example, as illustrated in FIG. 5B, in some implementations, one or more of the traces 532, e.g., a trace 562, can intersect a shadow of one or more of the contacts 538. In this context, the “shadow” of a component refers to a vertical projection of the component onto a layer above or below the component. For example, the shadow of a contact would include an area of a layer below the contact that is covered by the contact when the contact is viewed from above.

In the example illustrated in FIG. 5A, the device 500 includes an optional heat sink 590 coupled to an upper surface of the first IC device 502. Optionally, the device 500 can also, or alternatively, include a heat sink coupled to an upper surface of the second IC device 506. When present, the heat sink 590 facilitates dissipation of heat generated during operation of an IC device to which it is coupled.

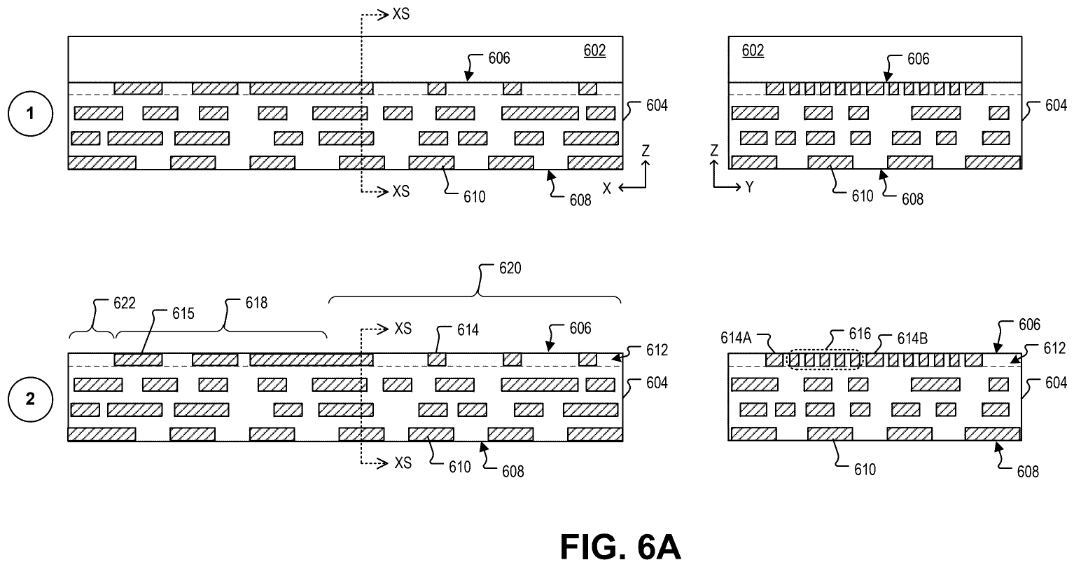

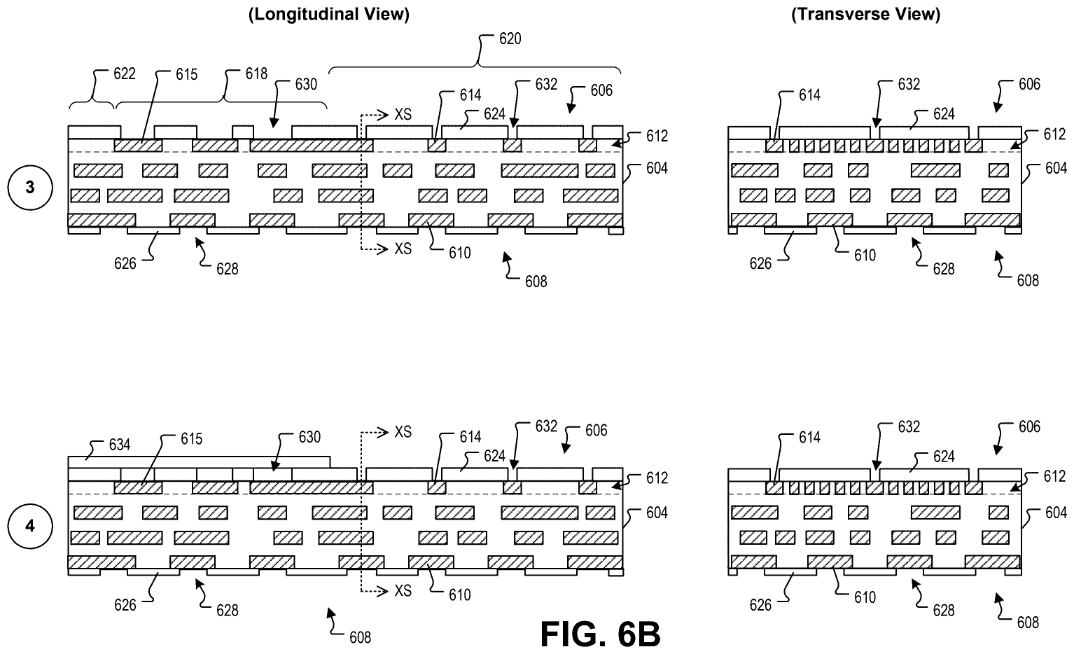

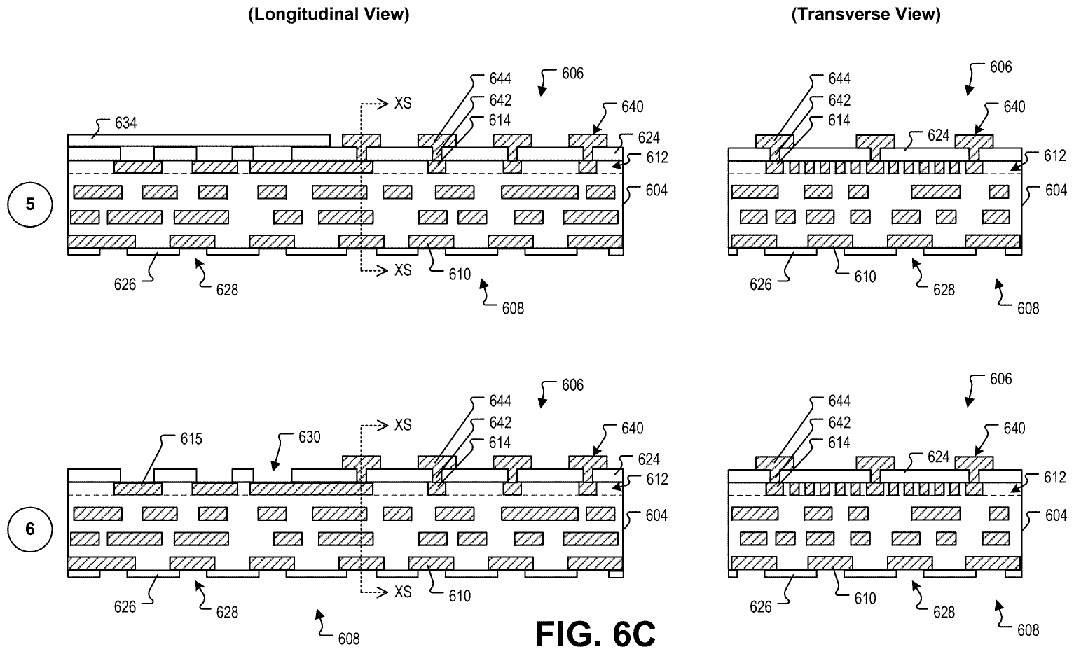

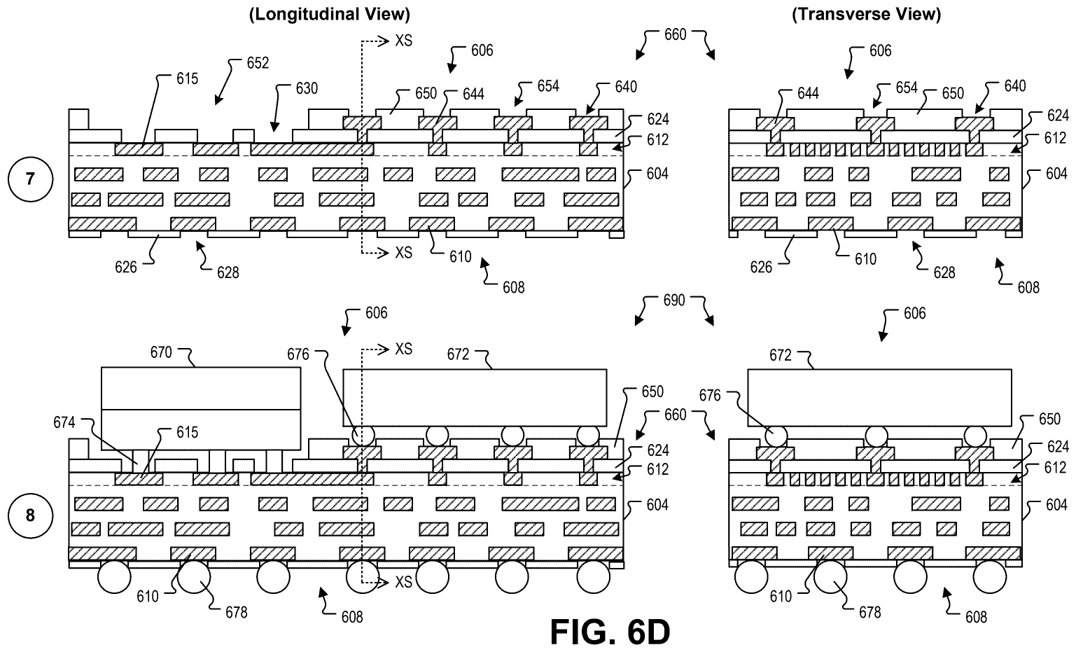

The exemplary device 500 illustrated in FIGS. 5A-5C solves the problems described above regarding routing conductive paths in a manner that provides desired signaling performance while also addressing other packaging concerns, such as cost, manufacturing complexity, and thickness. For example, the metal layer 520A of the first layer stack 512 can route more traces between adjacent via pads 530 than could be routed between adjacent contacts 538 which reduces the length of such traces 532 relative to traces that are routed through lower metal layers (e.g., metal layers 520B and below). Further, by enabling routing of more traces 532 on the metal layer 520A, the number of traces that need to be routed through the lower metal layers is reduced, which may enable reducing the number of metal layers of the first layer stack 512, resulting in decreased thickness and cost of the substrate 510. Additionally, a fabrication process to form the device 500 may have reduced complexity and cost as compared to fabrication processes of other devices with IC devices in a side-by-side arrangement because forming the first solder resist layer 534 and the second solder resist layer 546 across an entirety of the substrate 510 (e.g., in the first region 516, the second region 518, and the third region 519) involves a less complicated and costly process, as further described herein with reference to FIGS. 6A-6D, than forming the second layer stack 514 as a plateau on a PID layer that is only in the second region 518.

Exemplary Sequence for Fabricating a Device with Side-by-Side IC Devices on a Substrate that Includes Solder Resist Layer(s)

In some implementations, fabricating a device (e.g., the device 500 of FIGS. 5A-5C) includes several processes. FIGS. 6A-6D, together, illustrate an exemplary sequence for providing or fabricating that includes multiple IC devices interconnected in a side-by-side arrangement on a substrate that includes one or more solder resist layers, as described with reference to any of FIGS. 5A-5C.

In the example illustrated in FIGS. 6A-6D, various stages during fabrication of a device are shown, where each stage represents a state after performance of one or more fabrication operations. In some implementations, the order of performance of various operations can be changed or modified. In some implementations, one or more of the processes may be replaced or substituted without departing from the scope of the disclosure. In the following description, reference is made to various illustrative stages of the sequence, which are numbered (using circled numbers) in FIGS. 6A-6D. Each of the various stages of the sequence of FIGS. 6A-6D is illustrated with a schematic longitudinal cross-sectional profile view (“longitudinal view”) and a corresponding schematic transverse cross-section view (“transverse view”) along a cut line XS shown in the longitudinal view. The sequence of FIGS. 6A-6D illustrates stages of a sequence for fabricating a device that includes two IC devices interconnected in a side-by-side arrangement on a substrate that includes one or more solder resist layers; however, the sequence can be used to form devices with more than two IC devices.

Stage 1 of FIG. 6A illustrates a state after formation of a first layer stack 604 on a carrier substrate 602. The first layer stack 604 includes or corresponds to the first layer stack 512 of FIG. 5C. For example, the first layer stack 604 includes multiple metal layers (e.g., metal layers 520 of FIGS. 5A-5C) interspersed with multiple dielectric layers (e.g., dielectric layers 522 of FIGS. 5A-5C).

In the implementation illustrated in FIG. 6A, a first side 606 of the first layer stack 604 is adjacent to the carrier substrate 602, and a second side 608 of the first layer stack 604 is opposite the carrier substrate 602. In this implementation, the second side 608 includes a bottom metal layer of a substrate that is being formed (e.g., substrate 660 of FIG. 6D), and the bottom metal layer is patterned to form contacts 610. For example, the bottom metal layer may correspond to or include the metal layer 520D of FIG. 5A. The contacts 610 disposed on the second side 608 may correspond to or include the contacts 558 of FIG. 5A. In other implementations, the second side 608 is formed adjacent to the carrier substrate 602, leaving the first side 606 exposed at Stage 1.

The first layer stack 604 can be formed on the carrier substrate 602 using lamination techniques, such as patterning metal layers, application of dielectric layers, and formation of vias interconnecting various metal layers through the dielectric layers. In some implementations, deposition techniques can be used instead of or along with lamination techniques to form the first layer stack 604 on the carrier substrate 602. For example, deposition techniques can include deposition of metal layers, deposition of dielectric layers, and/or deposition of conductive vias.

Stage 2 illustrates a state of the first layer stack 604 after the carrier substrate 602 is removed. Removal of the carrier substrate 602, in the implementation illustrated, reveals the first side 606 of the first layer stack 604. The first side 606 includes a top metal layer 612 of the first layer stack 604. The top metal layer 612 is patterned, in a second region 620, to define one or more via pads 614 and, in a first region 618 and the second region 620, to define one or more traces 616 that extend between a pair of adjacent via pads (e.g., a via pad 614A and a via pad 614B). The top metal layer 612 is also patterned, in the first region 618, to define contacts 615 that are configured to electrically connect to a first IC device (e.g., IC device 670 shown in FIG. 6D). The top metal layer 612 is not patterned in a third region 622 in implementations in which the third region 622 is an edge of a packaged device formed by the stages of the process shown in FIGS. 6A-6D. Alternatively, the top metal layer 612 can be patterned in the third region 622 to define one or more of the contacts 615.

Stage 3 of FIG. 6B illustrates a state of the first layer stack 604 after formation and patterning of a first solder resist layer 624 on the first side 606 of the first layer stack 604, and formation and patterning of a solder resist layer 626 on the second side 608. For example, the first solder resist layer 624 includes a material or compound that prevents formation of solder bridges, such as a dry film that is laminated onto the first side 606 or a liquid that is silkscreened or sprayed on to the first side 606. In some implementations, the dry film or the liquid can be photo-imageable to enable patterning to form features. In a particular aspect, the first solder resist layer 624 includes or corresponds to the first solder resist layer 534 of FIGS. 5A-5C. The first solder resist layer 624 may be formed in particular areas (e.g., between contacts) or may be patterned to define openings 630 exposing portions of the contacts 615 and to define openings 632 exposing portions of via pads 614. The solder resist layer 626 is patterned to include openings 628 that provide access to the contacts 610 that are configured to provide off-device conductive pathways. In implementations in which the first solder resist layer 624 and/or the solder resist layer 626 include photo-imageable solder resist films, patterning the first solder resist layer 624 and/or the solder resist layer 626 includes exposing portions of the first solder resist layer 624 and/or the solder resist layer 626 to light to define a pattern (or a reverse pattern) and developing the first solder resist layer 624 and/or the solder resist layer 626 to remove uncured portions of the first solder resist layer 624 and/or the solder resist layer 626.

Stage 4 illustrates a state after formation and patterning of a mask layer 634. For example, the mask layer 634 can be laminated onto the first side 606. The mask layer 634 is patterned to cover the openings 630, such as through exposure and developing, as described above for the first solder resist layer 624. The mask layer 634 may be a different material than the first solder resist layer 624, such as a photo-imageable dielectric layer or another type of material that protects the openings 630 during an upcoming metal deposition process.

Stage 5 of FIG. 6C illustrates a state after formation of conductive vias 642 and contacts 644. Each of the conductive vias 642 is electrically connected to a respective one of the via pads 614 and electrically connected to a respective contact 644. In the example illustrated, the contacts 644 and conductive vias 642 are formed as unitary structures (e.g., structures 640). For example, one or more metal deposition operations, guided by the openings 632 in the first solder resist layer 624, can be used to form the structures 640. Additionally, one or more photo resist layers may be used to pattern the deposited metal to form the contacts 644 having shapes that correspond to contacts on an IC die to be connected to the contacts 644.

Stage 6 illustrates a state after removal of the mask layer 634. For example, the mask layer 634 may be removed using one or more etching operations, one or more dry film stripping and/or removal operations, or a combination thereof. After removal of the mask layer 634, the openings 630 are uncovered and the contacts 615 are exposed.

Stage 7 of FIG. 6D illustrates a state after formation and patterning of a second solder resist layer 650 on the first side 606. The second solder resist layer 650 is patterned to include an opening 652 that provides access to the openings 630 and the contacts 615 that are configured to be electrically connected to an IC device (e.g., the IC device 670 of FIG. 6D). The second solder resist layer 650 is also patterned to include openings 654 that provide access to the contacts 644 that are configured to be electrically connected to another IC device (e.g., the IC device 672 of FIG. 6D). Formation of a substrate 660 is complete at Stage 7 of FIG. 6D. A second layer stack of the substrate 660 formed in the second region 620 may include portion(s) of the first solder resist layer 624, the conductive vias 642, the contacts 644, and the second solder resist layer 650.

Formation of a device 690 is complete at Stage 8 of FIG. 6D. Stage 8 illustrates a state after an IC device 670 and an IC device 672 are attached to the substrate 660. The IC device 670 is connected, via interconnects 674 to the contacts 615. The IC device 670 includes or corresponds to the IC device 502 of any of FIGS. 5A-5C, and the interconnects 674 include or correspond to the interconnects 542 of FIG. 5A, which are electrically connected to the contacts 524 (illustrated, for example, in FIG. 5B). The IC device 672 is connected, via interconnects 676 to the contacts 644. The IC device 672 includes or corresponds to the IC device 506 of any of FIGS. 5A-5C, and the interconnects 676 include or correspond to the interconnects 544 of FIG. 5A, which are electrically connected to the contacts 538. In the example illustrated in FIG. 6D, the device 690 also includes interconnects 678 (e.g., an array of solder balls) electrically connected to the contacts 610 on the second side 608.

Although the device 690 is illustrated as including two IC devices 670, 672 coupled to a substrate 660, more than two IC devices can be coupled to the substrate 660. For example, additional regions that are similar to the first region 618 may define recesses in which other IC devices with relatively smaller interconnects may be coupled. As another example, additional regions that are similar to the second region 620 may include additional via pads, conductive vias, and additional metal layers to form contacts for other IC devices with relatively larger interconnects.

The device 690 solves problems related to routing conductive paths in a manner that provides desired signaling performance while also addressing other packaging concerns, such as cost, manufacturing complexity, and thickness. For example, the top metal layer 612 of the first layer stack 604 can route more traces 616 between adjacent via pads 614 (annotated in FIG. 6A) than could be routed between adjacent contacts 644 which reduces the length of such traces 616 relative to traces that are routed through lower metal layers of the first layer stack 604. Further, by enabling routing of more traces 616 on the top metal layer 612 of the first layer stack 604, the number of traces that need to be routed through the lower metal layers is reduced, which may enable reducing the number of metal layers of the first layer stack 604, resulting in decreased thickness and cost of the substrate 660. Additionally, forming and patterning solder resist layers, such as the first solder resist layer 624 and the second solder resist layer 650, across an entirety of the substrate 660 (e.g., across multiple regions, such as the first region 618, the second region 620, and the third region 622) results in the device 690 formed on the substrate 660 having uniform height (e.g., due to the second solder resist layer 650 being the top of the substrate 660) and reduces complexity and cost of the fabrication process as compared to forming a plateau on a photo-imageable dielectric layer, as described in FIGS. 4A-4E, in which the substrate 450 has non-uniform height.

Exemplary Flow Diagram of a Method for Fabricating a Device with Side-by-Side IC Devices

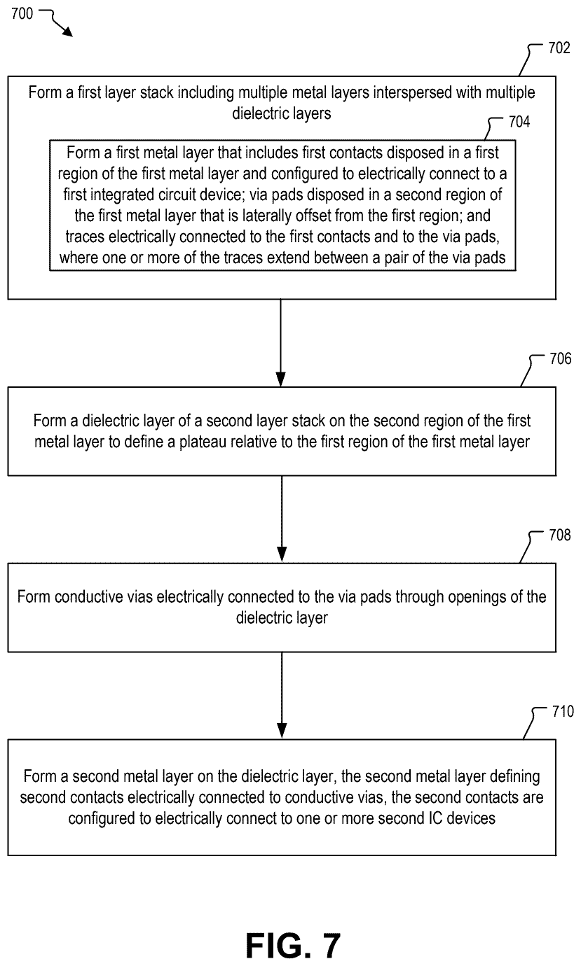

In some implementations, fabricating a device with side-by-side IC devices includes several processes. FIG. 7 illustrates an exemplary flow diagram of a method 700 for providing or fabricating a device. In some implementations, the method 700 of FIG. 7 may be used to provide or fabricate any of the devices 100, 200, or 300 of FIGS. 1A-3B.

It should be noted that the method 700 of FIG. 7 may combine one or more processes in order to simplify and/or clarify the method for providing or fabricating a device. In some implementations, the order of the processes may be changed or modified.

The method 700 includes, at block 702, forming a first layer stack including multiple metal layers interspersed with multiple dielectric layers. Forming the first layer stack includes, at block 704, forming a first metal layer that includes first contacts, via pads, and traces. The first contacts are disposed in a first region of the first metal layer and configured to electrically connect to a first IC device. The via pads are disposed in a second region of the first metal layer that is laterally offset from the first region. The traces are electrically connected to the first contacts and to the via pads, and one or more of the traces extend between a pair of the via pads. For example, the first layer stack may include or correspond to the first layer stack 112 of FIG. 1C or the first layer stack 404 of FIG. 4A. To illustrate, the first layer stack 404 of FIG. 4A includes contacts 456 (annotated in FIG. 4E) in a first region 418 and via pads 414 in a second region offset from the first region 418. The first layer stack 404 also includes traces 416 extending between pairs of the via pads 414. In a particular implementation, the contacts 456, the via pads 414, and the traces 416 are formed on the carrier substrate 402 resulting in a substantially coplanar upper surface (e.g., on the first side 406) of the contacts 456, the via pads 414, and the traces 416. The first layer stack can be formed using lamination techniques, deposition techniques, patterning techniques, or combinations thereof.

The method 700 includes, at block 706, forming a dielectric layer of a second layer stack on the second region of the first metal layer to define a plateau relative to the first region of the first metal layer. For example, the second layer stack can include or correspond to the second layer stack 114 of FIG. 1C, and the dielectric layer can include the dielectric layer 134. The dielectric layer can include, for example, a photo-imageable dielectric.

The method 700 includes, at block 708, forming conductive vias electrically connected to the via pads through openings of the dielectric layer, and at block 710, forming a second metal layer on the dielectric layer. In some implementations, the conductive vias and the second metal layer are formed concurrently. The second metal layer defines second contacts electrically connected to the conductive vias. The second contacts are configured to electrically connect to one or more second IC devices. For example, the second contacts can include or correspond to the second contacts 138 and the conductive vias can include or correspond to the conductive vias 140. As another example, the second contacts can include or correspond to the contacts 444 and the conductive vias can include or correspond to the conductive vias 442.

In some implementations, forming the first layer stack includes forming the multiple metal layers and the multiple dielectric layers on a carrier (e.g., the carrier substrate 402 of FIG. 4A). In such implementations, forming the first layer stack also includes removing the carrier to expose an upper surface of the first layer stack, where the upper surface of the first layer stack includes an upper surface of the first metal layer and an upper surface of a first dielectric layer of the first layer stack. The upper surface of the first metal layer may subsequently be etched to recess the first metal layer below the upper surface of the first dielectric layer of the first layer stack.

In some implementations, forming the dielectric layer of the second layer stack includes forming a photo-imageable dielectric (PID) layer coupled to the upper surface of the first dielectric layer of the first layer stack at least in the second region and forming openings in the PID layer to the via pads. In such implementations, forming the second metal layer also includes forming a resist layer on the PID layer and depositing metal, guided by the resist layer, to define the second contacts electrically connected to the conductive vias. For example, forming the conductive vias may include depositing metal within the openings of the PID layer and electrically connected to the via pads. To illustrate, the conductive vias and the second contacts can be deposited together as guided by the openings 432 and the openings 436 of FIG. 4C.

Exemplary Flow Diagram of a Method for Fabricating a Device with Side-by-Side IC Devices on a Substrate that Includes Solder Resist Layer(s)

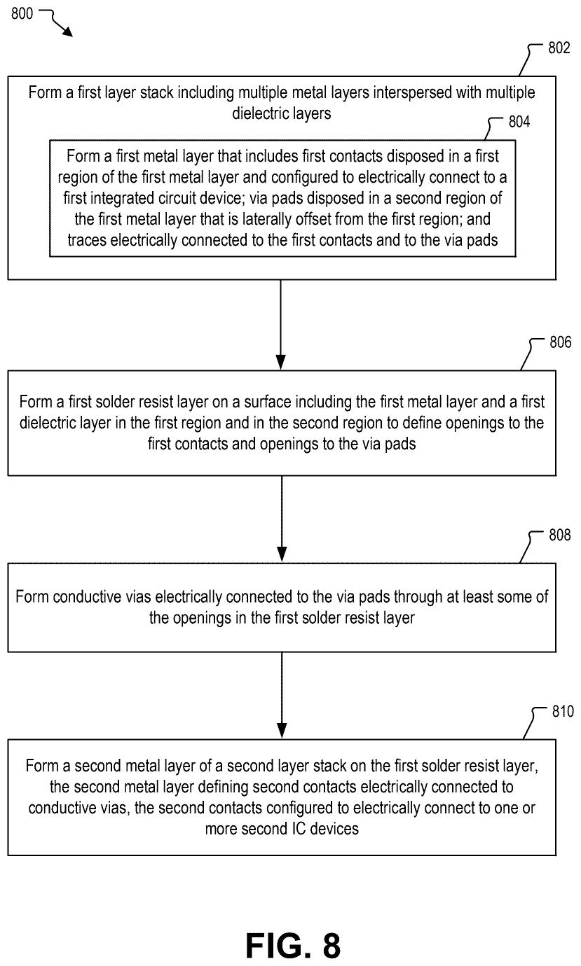

In some implementations, fabricating a device with side-by-side IC devices on a substrate that includes one or more solder resist layers includes several processes. FIG. 8 illustrates an exemplary flow diagram of a method 800 for providing or fabricating a device. In some implementations, the method 800 of FIG. 8 may be used to provide or fabricate the device 500 of FIGS. 5A-5C.

It should be noted that the method 800 of FIG. 8 may combine one or more processes in order to simplify and/or clarify the method for providing or fabricating a device. In some implementations, the order of the processes may be changed or modified.

The method 800 includes, at block 802, forming a first layer stack including multiple metal layers interspersed with multiple dielectric layers. Forming the first layer stack includes, at block 804, forming a first metal layer that includes first contacts, via pads, and traces. The first contacts are disposed in a first region of the first metal layer and configured to electrically connect to a first IC device. The via pads are disposed in a second region of the first metal layer that is laterally offset from the first region. The traces are electrically connected to the first contacts and to the via pads. For example, the first layer stack may include or correspond to the first layer stack 512 of FIG. 5C or the first layer stack 604 of FIG. 6A. To illustrate, the first layer stack 604 of FIG. 6A includes contacts 615 in a first region 618 and via pads 614 in a second region 620 offset from the first region 618. The first layer stack 604 also includes traces 616. In some implementations, one or more of the traces extend between a pair of the via pads. For example, at least some of traces 616 extend between pairs of the via pads 614, as shown in FIG. 6A. In a particular implementation, the contacts 615, the via pads 614, and the traces 616 are formed on the carrier substrate 602 resulting in a substantially coplanar upper surface (e.g., on the first side 606) of the contacts 615, the via pads 614, and the traces 616. The first layer stack can be formed using lamination techniques, deposition techniques, patterning techniques, or combinations thereof.

The method 800 includes, at block 806, forming a first solder resist layer on a surface including the first metal layer and a first dielectric layer in the first region and in the second region. The first solder resist layer defines openings to the first contacts and openings to the via pads. For example, the first solder resist layer can include or correspond to the first solder resist layer 546 of FIG. 5A, the openings to the first contacts may include or correspond to the openings 548 of FIG. 5A, and the openings to the via pads may include or correspond to the openings that are filled by the conductive vias 540 of FIG. 5A. As another example, the first solder resist layer can include or correspond to the first solder resist layer 624 of FIGS. 6B-6D that defines the openings 630 to the contacts 615 and the openings 632 to the via pads 614.

The method 800 includes, at block 808, forming conductive vias electrically connected to the via pads through at least some of the openings in the first solder resist layer, and at block 810, forming a second metal layer of a second material stack on the first solder resist layer. For example, the conductive vias can include or correspond to the conductive vias 540 of FIG. 5A or the conductive vias 642 of FIGS. 6C-6D, the second layer stack can include or correspond to the second layer stack 514 of FIG. 5C or the second layer stack of FIG. 6D that includes portion(s) of the first solder resist layer 624, the via pads 614, the conductive vias 642, the contacts 644, and the second solder resist layer 650, and the second metal layer can include or correspond to the metal layer 536 of FIG. 5A or the metal layer that defines the contacts 644 of FIGS. 6C-6D. In some implementations, the conductive vias and the second metal layer are formed concurrently. The second metal layer defines second contacts electrically connected to the conductive vias. The second contacts are configured to electrically connect to one or more second IC devices. For example, the second contacts can include or correspond to the contacts 538 of FIG. 5A or the contacts 644 of FIGS. 6C-6D, and the one or more second IC devices can include or correspond to the second IC device 506 of FIG. 5A or the IC device 672 of FIG. 6D.

In some implementations, forming the first layer stack includes forming the multiple metal layers and the multiple dielectric layers on a carrier (e.g., the carrier substrate 602 of FIG. 6A). In such implementations, forming the first layer stack also includes removing the carrier to expose an upper substrate surface, where the upper substrate surface includes an upper surface of the first metal layer and an upper surface of a dielectric layer. The upper surface of the first metal layer may subsequently be etched to recess the first metal layer below the upper surface of the dielectric layer.

In some implementations, the first solder resist layer is formed on the surface in the first region, in the second region, and in a third region during a first solder resist process. The third region is laterally offset from the first region in an opposite direction of the second region. For example, the first region can include or correspond to the first region 516 of FIG. 5A, the second region can include or correspond to the second region 518 of FIG. 5A, and the third region can include or correspond to the third region 519 of FIG. 5A. In some such implementations, forming the conductive vias includes depositing metal within at least some of the openings in the first solder resist layer and electrically connected to the via pads. To illustrate, metal may be deposited in the openings 632 of FIG. 6B on the via pads 614 to form the conductive vias 642 of FIGS. 6C-6D. In some such implementations, the method 800 further includes forming a second solder resist layer on the first solder resist layer and at least a portion of the second contacts during a second solder resist process. For example, the second solder resist layer can include or correspond to the second solder resist layer 546 of FIG. 5A or the second solder resist layer 650 of FIG. 6D. In some such implementations, the second solder resist layer defines an opening in the first region that exposes the first contacts. For example, the opening may include or correspond to the opening 652 of FIG. 6D that reveals the openings 630 and exposes the contacts 615.

### Exemplary Electronic Devices

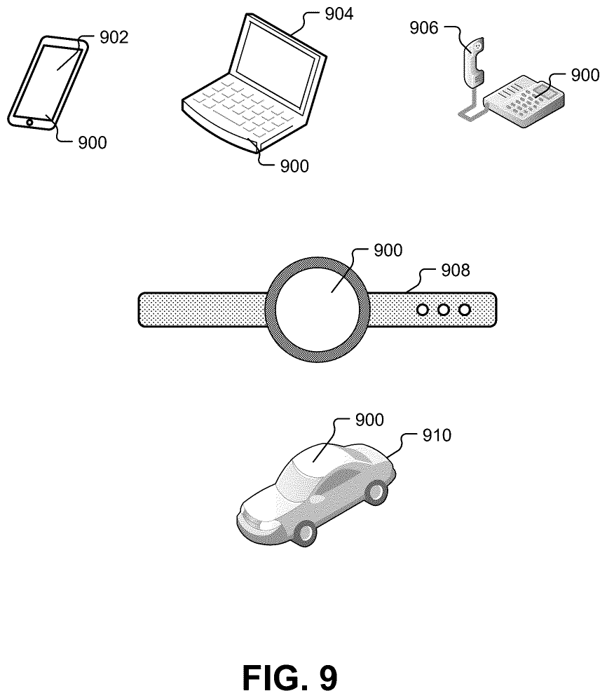

FIG. 9 illustrates various electronic devices that may include or be integrated with any of the devices 100, 200, 300, or 500. For example, a mobile phone device 902, a laptop computer device 904, a fixed location terminal device 906, a wearable device 908, or a vehicle 910 (e.g., an automobile or an aerial device) may include a device 900. The device 900 can include, for example, any of the devices 100, 200, 300, or 500 described herein. The devices 902, 904, 906 and 908 and the vehicle 910 illustrated in FIG. 9 are merely exemplary. Other electronic devices may also feature the device 900 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in vehicles (e.g., autonomous vehicles), or any other device that stores or retrieves data or computer instructions, or any combination thereof.

One or more of the components, processes, features, and/or functions illustrated in FIGS. 1A-9 may be rearranged and/or combined into a single component, process, feature or function or embodied in several components, processes, or functions. Additional elements, components, processes, and/or functions may also be added without departing from the disclosure. It should also be noted that FIGS. 1A-9 and its corresponding description in the present disclosure is not limited to dies and/or ICs. In some implementations, FIGS. 1A-9 and its corresponding description may be used to manufacture, create, provide, and/or produce devices and/or integrated devices. In some implementations, a device may include a die, an integrated device, an integrated passive device (IPD), a die package, an integrated circuit (IC) device, a device package, an integrated circuit (IC) package, a wafer, a semiconductor device, a package-on-package (POP) device, a heat dissipating device and/or an interposer.

It is noted that the figures in the disclosure may represent actual representations and/or conceptual representations of various parts, components, objects, devices, packages, integrated devices, integrated circuits, and/or transistors. In some instances, the figures may not be to scale. In some instances, for purpose of clarity, not all components and/or parts may be shown. In some instances, the position, the location, the sizes, and/or the shapes of various parts and/or components in the figures may be exemplary. In some implementations, various components and/or parts in the figures may be optional.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling (e.g., mechanical coupling) between two objects. For example, if object A physically touches object B, and object B touches object C, then objects A and C may still be considered coupled to one another-even if they do not directly physically touch each other. An object A, that is coupled to an object B, may be coupled to at least part of object B. The term “electrically coupled” may mean that two objects are directly or indirectly coupled together such that an electrical current (e.g., signal, power, ground) may travel between the two objects. Two objects that are electrically coupled may or may not have an electrical current traveling between the two objects. The use of the terms “first”, “second”, “third” and “fourth” (and/or anything above fourth) is arbitrary. Any of the components described may be the first component, the second component, the third component or the fourth component. For example, a component that is referred to as a second component, may be the first component, the second component, the third component or the fourth component. The terms “encapsulate”, “encapsulating” and/or any derivation means that the object may partially encapsulate or completely encapsulate another object. The terms “top” and “bottom” are arbitrarily defined with respect to one or more of the orientations illustrated in the figures. However, it is noted that a component that is referred to and/or illustrated as a “top” component, can be located on a different side of a structure in a particular circumstance. In such situations, a particular component may literally be on the bottom or on a side of the structure and may nevertheless correspond to the “top” component referred to herein when viewed in the arbitrary orientation(s) illustrated. As described in the disclosure, a first component that is located “over” a second component may mean that the first component is located above or below the second component, depending on how a bottom or top is arbitrarily defined. In another example, a first component may be located over (e.g., above) a first surface of the second component, and a third component may be located over (e.g., below) a second surface of the second component, where the second surface is opposite to the first surface. It is further noted that the term “over” as used in the present application in the context of one component located over another component, may be used to mean a component that is on another component and/or in another component (e.g., on a surface of a component or embedded in a component). Thus, for example, a first component that is over the second component may mean that (1) the first component is over the second component, but not directly touching the second component, (2) the first component is on (e.g., on a surface of) the second component, and/or (3) the first component is in (e.g., embedded in) the second component. A first component that is located “in” a second component may be partially located in the second component or completely located in the second component. A value that is about X-XX, may mean a value that is between X and XX, inclusive of X and XX. The value(s) between X and XX may be discrete or continuous. The term “about ‘value X’”, or “approximately value X”, as used in the disclosure means within 10 percent of the ‘value X’. For example, a value of about 1 or approximately 1, would mean a value in a range of 0.9-1.1. A “plurality” of components may include all the possible components or only some of the components from all of the possible components. For example, if a device includes ten components, the use of the term “the plurality of components” may refer to all ten components or only some of the components from the ten components.

In some implementations, an interconnect is an element or component of a device or package that allows or facilitates an electrical connection between two points, elements and/or components. In some implementations, an interconnect may include a trace, a via, a pad, a pillar, a metallization layer, a redistribution layer, and/or an under bump metallization (UBM) layer/interconnect. In some implementations, an interconnect may include an electrically conductive material that may be configured to provide an electrical path for a signal (e.g., a data signal), ground and/or power. An interconnect may include more than one element or component. An interconnect may be defined by one or more interconnects. An interconnect may include one or more metal layers. An interconnect may be part of a circuit. Different implementations may use different processes and/or sequences for forming the interconnects. In some implementations, a chemical vapor deposition (CVD) process, a physical vapor deposition (PVD) process, a sputtering process, a spray coating, and/or a plating process may be used to form the interconnects.

Also, it is noted that various disclosures contained herein may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

In the following, further examples are described to facilitate the understanding of the disclosure.

According to Example 1, a device includes a substrate that includes a first layer stack including multiple metal layers interspersed with multiple dielectric layers. A first metal layer of the first layer stack includes first contacts disposed in a first region of the first metal layer and configured to electrically connect to a first integrated circuit (IC) device, via pads disposed in a second region of the first metal layer, the second region offset along a first direction from the first region, and traces electrically connected to the first contacts and to the via pads. The substrate also includes a first solder resist layer disposed on a surface including the first metal layer and a first dielectric layer in the first region and in the second region, the first solder resist layer defining openings to the first contacts and openings to the via pads. The substrate further includes a second layer stack disposed on the second region of the first metal layer. The second layer stack includes a second metal layer disposed on the first solder resist layer opposite the first layer stack, the second metal layer defining second contacts configured to electrically connect to one or more second IC devices. The second layer stack also includes conductive vias extending between the via pads and the second contacts.

Example 2 includes the device of Example 1, wherein the substrate further includes a third region offset along a second direction from the first region that is opposite of the first direction, and wherein at least a portion of the first solder resist layer is disposed on the first layer stack in the third region.

Example 3 includes the device of Example 1 or Example 2 and further includes a second solder resist layer disposed on at least a portion of the first solder resist layer and defining an opening in the first region.

Example 4 includes the device of Example 3, wherein the second solder resist layer is disposed on at least a portion of the second metal layer.

Example 5 includes the device of Example 3 or 4, wherein a first portion of the second solder resist layer is disposed on the portion of the first solder resist layer in the third region, and wherein a second portion of the second solder resist layer is disposed on a portion of the first solder resist layer in the second region.

Example 6 includes the device of any of Examples 1 to 5, wherein the first IC device includes first circuitry forming one or more processor cores and the one or more second IC devices include second circuitry forming one or more memory cells.

Example 7 includes the device of any of Examples 1 to 6, wherein the first layer stack further includes external contacts, and wherein the external contacts are electrically connected, by conductive paths of the multiple metal layers, to the first contacts, the second contacts, or both, to provide off-package connections.

Example 8 includes the device of any of Examples 1 to 7, wherein one or more of the traces intersect a shadow of one or more of the second contacts.

Example 9 includes the device of any of Examples 1 to 8, wherein a characteristic dimension of the second contacts is greater than a characteristic dimension of the via pads, and wherein a pitch of the via pads is approximately equal to a pitch of the second contacts.

Example 10 includes the device of any of Examples 1 to 9 and further includes the first IC device electrically connected, via a first array of interconnects, to the first contacts. The device also includes the one or more second IC devices electrically connected, via a second array of interconnects, to the second contacts.

Example 11 includes the device of Example 10, wherein the first IC device includes a semiconductor die and the one or more second IC devices include a surface-mountable package.

According to Example 12, a method for fabricating a device includes forming a first layer stack including multiple metal layers interspersed with multiple dielectric layers. Forming the first layer stack includes forming a first metal layer that includes: first contacts disposed in a first region of the first metal layer and configured to electrically connect to a first IC device; via pads disposed in a second region of the first metal layer that is laterally offset from the first region; and traces electrically connected to the first contacts and to the via pads. The method also includes forming a first solder resist layer on a surface including the first metal layer and a first dielectric layer in the first region and in the second region, the first solder resist layer defining openings to the first contacts and openings to the via pads. The method also includes forming conductive vias electrically connected to the via pads through at least some of the openings in the first solder resist layer. The method also includes forming a second metal layer of a second layer stack on the first solder resist layer, the second metal layer defining second contacts electrically connected to the conductive vias, the second contacts configured to electrically connect to one or more second IC devices.

Example 13 includes the method of Example 12, wherein forming the first layer stack includes forming the multiple metal layers and the multiple dielectric layers on a carrier and removing the carrier to expose an upper substrate surface of the first layer stack, where the upper substrate surface of the first layer stack includes an upper surface of the first metal layer and an upper surface of a first dielectric layer of the first metal layer. Forming the first layer stack also includes etching the upper surface of the first metal layer to recess the first metal layer below the upper surface of the first dielectric layer of the first layer stack.

Example 14 includes the method of Example 12 or Example 13, wherein the first solder resist layer is formed on the surface in the first region, in the second region, and in a third region during a first solder resist process, and wherein the third region is laterally offset from the first region in an opposite direction of the second region.

Example 15 includes the method of any of Examples 12 to 14, wherein forming the conductive vias includes depositing metal within at least some of the openings in the first solder resist layer and electrically connected to the via pads.

Example 16 includes the method of any of Examples 12 to 15 and further includes forming a second solder resist layer on the first solder resist layer and at least a portion of the second contacts during a second solder resist process.

Example 17 includes the method of Example 16, wherein the second solder resist layer defines an opening in the first region that exposes the first contacts.

According to Example 18, a device includes one or more first IC devices, one or more second IC devices, and a substrate coupled to the one or more first IC devices and the second IC devices and defining conductive paths therebetween. The substrate includes a first layer stack including multiple metal layers interspersed with multiple dielectric layers. A first metal layer of the first layer stack includes first contacts disposed in a first region of the first metal layer and electrically connected to the one or more first IC devices. The first metal layer also includes via pads disposed in a second region of the first metal layer, where the second region is offset along a first direction from the first region. The first metal layer also includes traces electrically connected to the first contacts and to the via pads. The substrate also includes a first solder resist layer disposed on a surface including the first metal layer and a first dielectric layer in the first region and in the second region, the first solder resist layer defining openings to the first contacts and openings to the via pads. The substrate further includes a second layer stack disposed on the second region of the first metal layer. The second layer stack includes a second metal layer disposed on the first solder resist layer opposite the first layer stack. The second metal layer defines second contacts electrically connected to the one or more second IC devices. The second layer stack also includes conductive vias extending between the via pads and the second contacts.

Example 19 includes the device of Example 18, wherein the substrate further includes a second solder resist layer disposed on at least a portion of the first solder resist layer and at least a portion of the second metal layer, the second solder resist layer defining an opening in the first region, and wherein the first IC device is disposed within the opening.

Example 20 includes the device of Example 18 or Example 19, wherein one or more of the traces extend between a pair of the via pads.

The various features of the disclosure described herein can be implemented in different systems without departing from the disclosure. It should be noted that the foregoing aspects of the disclosure are merely examples and are not to be construed as limiting the disclosure. The description of the aspects of the present disclosure is intended to be illustrative, and not to limit the scope of the claims. As such, the present teachings can be readily applied to other types of apparatuses and many alternatives, modifications, and variations will be apparent to those skilled in the art.

1. A device comprising:
a substrate comprising:
a first layer stack comprising multiple metal layers interspersed with multiple dielectric layers, wherein a first metal layer of the first layer stack comprises:
first contacts disposed in a first region of the first metal layer and configured to electrically connect to a first integrated circuit (IC) device;
via pads disposed in a second region of the first metal layer, the second region offset along a first direction from the first region; and
traces electrically connected to the first contacts and to the via pads;
a first solder resist layer disposed on a surface including the first metal layer and a first dielectric layer in the first region and in the second region, the first solder resist layer defining openings to the first contacts and openings to the via pads; and
a second layer stack disposed on the second region of the first metal layer, the second layer stack comprising:
a second metal layer disposed on the first solder resist layer opposite the first layer stack, the second metal layer defining second contacts configured to electrically connect to one or more second IC devices; and
conductive vias extending between the via pads and the second contacts.

2. The device of claim 1, wherein the substrate further comprises a third region offset along a second direction from the first region that is opposite of the first direction, and wherein at least a portion of the first solder resist layer is disposed on the first layer stack in the third region.

3. The device of claim 2, further comprising a second solder resist layer disposed on at least a portion of the first solder resist layer and defining an opening in the first region.

4. The device of claim 3, wherein the second solder resist layer is disposed on at least a portion of the second metal layer.

5. The device of claim 3, wherein a first portion of the second solder resist layer is disposed on the portion of the first solder resist layer in the third region, and wherein a second portion of the second solder resist layer is disposed on a portion of the first solder resist layer in the second region.

6. The device of claim 1, wherein the first IC device includes first circuitry forming one or more processor cores and the one or more second IC devices include second circuitry forming one or more memory cells.

7. The device of claim 1, wherein the first layer stack further comprises external contacts, and wherein the external contacts are electrically connected, by conductive paths of the multiple metal layers, to the first contacts, the second contacts, or both, to provide off-package connections.

8. The device of claim 1, wherein one or more of the traces intersect a shadow of one or more of the second contacts.

9. The device of claim 1, wherein a characteristic dimension of the second contacts is greater than a characteristic dimension of the via pads, and wherein a pitch of the via pads is approximately equal to a pitch of the second contacts.

10. The device of claim 1, further comprising:
the first IC device electrically connected, via a first array of interconnects, to the first contacts; and
the one or more second IC devices electrically connected, via a second array of interconnects, to the second contacts.

11. The device of claim 10, wherein the first IC device comprises a semiconductor die and the one or more second IC devices comprise a surface-mountable package.

12. A method for fabricating a device, the method comprising:
forming a first layer stack comprising multiple metal layers interspersed with multiple dielectric layers, wherein forming the first layer stack includes forming a first metal layer that includes:
first contacts disposed in a first region of the first metal layer and configured to electrically connect to a first integrated circuit (IC) device;
via pads disposed in a second region of the first metal layer that is laterally offset from the first region; and
traces electrically connected to the first contacts and to the via pads;
forming a first solder resist layer on a surface including the first metal layer and a first dielectric layer in the first region and in the second region, the first solder resist layer defining openings to the first contacts and openings to the via pads;
forming conductive vias electrically connected to the via pads through at least some of the openings in the first solder resist layer; and
forming a second metal layer of a second layer stack on the first solder resist layer, the second metal layer defining second contacts electrically connected to the conductive vias, the second contacts configured to electrically connect to one or more second IC devices.

13. The method of claim 12, wherein forming the first layer stack comprises:
forming the multiple metal layers and the multiple dielectric layers on a carrier;
removing the carrier to expose an upper substrate surface, wherein the upper substrate surface includes an upper surface of the first metal layer and an upper surface of a first dielectric layer; and
etching the upper surface of the first metal layer to recess the first metal layer below the upper surface of the first dielectric layer of the first layer stack.

14. The method of claim 12, wherein the first solder resist layer is formed on the surface in the first region, in the second region, and in a third region, and wherein the third region is laterally offset from the first region in an opposite direction of the second region.

15. The method of claim 12, wherein forming the conductive vias comprises depositing metal within at least some of the openings in the first solder resist layer and electrically connected to the via pads.

16. The method of claim 12, further comprising forming a second solder resist layer on the first solder resist layer and at least a portion of the second contacts.

17. The method of claim 16, wherein the second solder resist layer defines an opening in the first region that exposes the first contacts.

18. A device comprising:
one or more first integrated circuit (IC) devices;
one or more second IC devices; and
a substrate coupled to the one or more first IC devices and the second IC devices and defining conductive paths therebetween, the substrate comprising:
a first layer stack comprising multiple metal layers interspersed with multiple dielectric layers, wherein a first metal layer of the first layer stack comprises:
first contacts disposed in a first region of the first metal layer and electrically connected to the one or more first IC devices;
via pads disposed in a second region of the first metal layer, the second region offset along a first direction from the first region; and
traces electrically connected to the first contacts and to the via pads;
a first solder resist layer disposed on a surface including the first metal layer and a first dielectric layer in the first region and in the second region, the first solder resist layer defining openings to the first contacts and openings to the via pads; and
a second layer stack disposed on the second region of the first metal layer, the second layer stack comprising:
a second metal layer disposed on the first solder resist layer opposite the first layer stack, the second metal layer defining second contacts electrically connected to the one or more second IC devices; and
conductive vias extending between the via pads and the second contacts.

19. The device of claim 18, wherein the substrate further comprises a second solder resist layer disposed on at least a portion of the first solder resist layer and at least a portion of the second metal layer, the second solder resist layer defining an opening in the first region, and wherein the first IC device is disposed within the opening.

20. The device of claim 18, wherein one or more of the traces extend between a pair of the via pads.
